(19) United States
(12) Patent Application Publication
(10) Pub. No.: US 2016/0083834 A1
(43) Pub. Date: Mar. 24, 2016

(54) Film Formation Apparatus, Shadow Mask, Film Formation Method, and Cleaning Method

(71) Applicant: Semiconductor Energy Laboratory Co., Ltd., Kanagawa-ken (JP)

(72) Inventors: Shunpei YAMAZAKI, Tokyo (JP); Fumito ISAKA, Zama (JP); Takashi ISHIZAKA, Atsugi (JP)

(73) Assignee: Semiconductor Energy Laboratory Co., Ltd., Kanagawa-ken (JP)

(21) Appl. No.: 14/856,877

(22) Filed: Sep. 17, 2015

(30) Foreign Application Priority Data
Sep. 19, 2014 (JP) 2014-191234

(51) Int. Cl. C23C 14/24; C23C 14/04

(52) U.S. Cl. CPC C23C 14/24; C23C 14/042

(57) ABSTRACT

A novel film formation apparatus is provided. A novel film formation method and cleaning method is also provided. Further, a novel shadow mask is provided. The inventors have conceived a structure including a film formation chamber and an adhesive layer that is on the inner wall of the film formation chamber and/or on the shadow mask and to which a film formation material is to be attached.

### BACKGROUND OF THE INVENTION

1. Field of the Invention

One embodiment of the present invention relates to a film formation apparatus, a film formation method, or a cleaning method.

Note that one embodiment of the present invention is not limited to the above technical field. The technical field of one embodiment of the invention disclosed in this specification and the like relates to an object, a method, or a manufacturing method. In addition, one embodiment of the present invention relates to a process, a machine, manufacture, or a composition of matter. Specifically, examples of the technical field of one embodiment of the present invention disclosed in this specification include a semiconductor device, a display device, a light-emitting device, a power storage device, a memory device, a method for driving any of them, and a method for manufacturing any of them.

2. Description of the Related Art

There is a known film formation apparatus that includes a film formation chamber provided with an evaporation source, a shadow mask transfer mechanism, a plasma source, a first mode, and a second mode (Patent Document 1). In the first mode, a film formation material ejected from the evaporation source is deposited on a film formation object while the shadow mask transfer mechanism transfers the film formation object overlapping with a shadow mask. In the second mode, the evaporation source is isolated from the plasma source by a gate valve, and plasma is delivered from the plasma source to remove the film formation material attached to the shadow mask while the shadow mask transfer mechanism holds and transfers the shadow mask. In this film formation apparatus, the film formation material attached to the shadow mask can be removed.

There is another known film formation apparatus that includes a film formation chamber provided with an evaporation source, a removal chamber provided with a parallel-plate plasma source and a shadow mask stage, two gate valves that are provided between the film formation chamber and the removal chamber so as to be apart from each other, a shadow mask transfer mechanism, a film formation mode, and a cleaning mode (Patent Document 2). In the film formation mode, a film is formed on a film formation object which overlaps with the shadow mask transferred by the shadow mask transfer mechanism. In the cleaning mode, plasma is delivered from the plasma source to the shadow mask supported on the shadow mask stage between an upper electrode and a bottom electrode of the parallel-plate plasma source. In this film formation apparatus, film formation can be performed using the shadow mask and a film formation material attached to the shadow mask can be removed.

### REFERENCES

### Patent Documents

### [Patent Document 1] Japanese Published Patent Application No. 2013-189707

### [Patent Document 2] Japanese Published Patent Application No. 2014-007387

### SUMMARY OF THE INVENTION

An object of one embodiment of the present invention is to provide a novel film formation apparatus that is highly convenient or reliable. Another object of one embodiment of the present invention is to provide a novel film formation method that is highly convenient or reliable. Another object of one embodiment of the present invention is to provide a novel cleaning method that is highly convenient or reliable. Another object of one embodiment of the present invention is to provide a novel film formation apparatus, a novel film formation method, or a novel cleaning method.

Note that the description of these objects does not disturb the existence of other objects. In one embodiment of the present invention, there is no need to achieve all the objects. Other objects will be apparent from and can be derived from the description of the specification, the drawings, the claims, and the like.

One embodiment of the present invention is a film formation apparatus including a processed member support configured to support a processed member, an evaporation source configured to eject a film formation material that is to be attached to the processed member, an adhesive layer to which the film formation material is to be attached, and a film formation chamber including the processed member support, the evaporation source, and the adhesive layer. The adhesive layer includes a region facing the evaporation source.

The aforementioned film formation apparatus of one embodiment of the present invention includes the film formation chamber and the adhesive layer that is on the inner wall of the film formation chamber and to which the film formation material is to be attached. This allows suppression of dust generated from the film formation material attached to the inner wall of the film formation chamber. As a result, a novel film formation apparatus can be provided.

One embodiment of the present invention is a film formation apparatus including a processed member support configured to support a processed member, an evaporation source configured to eject a film formation material that is to be attached to the processed member, a shadow mask support which is between the processed member and the evaporation source and is configured to support a shadow mask, an adhesive layer to which the film formation material is to be attached, and a film formation chamber including the processed member support, the evaporation source, the shadow mask support, and the adhesive layer. The adhesive layer is provided on the shadow mask so as to have a region facing the evaporation source.

In the aforementioned film formation apparatus of one embodiment of the present invention, the adhesive layer to which the film formation material is attached is on the evaporation source side of the shadow mask. This allows suppression of dust generated from the film formation material attached to the evaporation source side of the shadow mask. As a result, a novel film formation apparatus can be provided.

One embodiment of the present invention is the aforementioned film formation apparatus in which the adhesive layer with a width of 25 mm has an adhesion strength of 1 N to 20 N. Note that the adhesion strength in this specification refers to 180° peel strength on a stainless steel plate.

In the aforementioned film formation apparatus of one embodiment of the present invention, a material having an adhesion strength of 1 N to 20 N in a 25-mm-wide sample is used for the adhesive layer. This allows suppression of removal of the film formation material attached to the adhesive layer from the adhesive layer and suppression of dust generated from the film formation material attached to the adhesive layer. As a result, a novel film formation apparatus can be provided.

One embodiment of the present invention is the aforementioned film formation apparatus including a plasma source from which plasma is delivered to the adhesive layer, and a plasma source support which supports the plasma source and moves relatively to the adhesive layer.

The aforementioned film formation apparatus of one embodiment of the present invention includes the plasma source from which plasma is delivered to the adhesive layer. This allows removal of the film formation material attached to the adhesive layer and suppression of dust generated from the film formation material attached to the adhesive layer. As a result, a novel film formation apparatus can be provided.

One embodiment of the present invention is a film formation method and a cleaning method using the aforementioned film formation apparatus. The methods include a first step of evacuating the film formation chamber, a second step of ejecting the film formation material so that the film formation material is deposited on a surface of a processed member while the film formation material is attached to the adhesive layer, and a third step of delivering plasma from the plasma source to the adhesive layer to remove the film formation material.

The aforementioned film formation method and cleaning method of one embodiment of the present invention include the step of depositing the film formation material on the surface of the processed member while attaching the film formation material to the adhesive layer, and the step of delivering plasma from the plasma source to the adhesive layer to remove the film formation material. This allows suppression of dust generated from the film formation material attached to the adhesive layer and removal of the film formation material attached to the adhesive layer with use of plasma. As a result, a novel film formation method and cleaning method can be provided.

One embodiment of the present invention is a shadow mask including a shielding region configured to shield a film formation material and an opening region surrounded by the shielding region. The shielding region includes a base and a resin layer in contact with the base. The resin layer is configured to be separated from the base.

The shadow mask of one embodiment of the present invention includes the base and the resin layer that can be separated from the base and is on the side of the base that is in contact with the processed member. Accordingly, for example, dust attached to the processed member can be transferred to the resin layer to be removed. Moreover, dust transferred to the resin layer can also be separated from the base along with the resin layer. As a result, a novel shadow mask can be provided.

One embodiment of the present invention is the aforementioned shadow mask including the resin layer provided with a protruding part. The protruding part is adjacent to the opening region, and the protruding part is narrower than the shielding region.

In the shadow mask of one embodiment of the present invention, the resin layer that can be separated from the base and includes the protruding part is provided in the shielding region adjacent to the opening region. Accordingly, for example, the area of a part in contact with the processed member can be reduced to be equal to the area of the protruding part, so that dust attached to the shielding region is unlikely to be transferred to the processed member by contact. As a result, a novel shadow mask can be provided.

One embodiment of the present invention is a shadow mask including a shielding region configured to shield a film formation material and an opening region surrounded by the shielding region. An adhesive layer is provided on a surface of the shielding region.

The aforementioned shadow mask of one embodiment of the present invention includes the adhesive layer that is on the surface of the shielding region and to which the film formation material is to be attached. This allows suppression of dust generated from the film formation material attached to the shadow mask. As a result, a novel shadow mask can be provided.

A light-emitting device includes the following in its category: a module to which a connector such as a flexible printed circuit (FPC) or a tape carrier package (TCP) is attached; a module having a TCP provided with a printed wiring board at the end thereof; and a substrate over which an integrated circuit (IC) is mounted by a chip on glass (COG) method and a light-emitting element is formed.

According to one embodiment of the present invention, a novel film formation apparatus that is highly convenient or reliable can be provided. Alternatively, a novel shadow mask that is highly convenient or reliable can be provided. Alternatively, a novel film formation method that is highly convenient or reliable can be provided. Alternatively, a novel cleaning method that is highly convenient or reliable can be provided. Alternatively, a novel film formation method, a novel shadow mask, a novel evaporation method, or a novel cleaning method can be provided.

Note that the description of these effects does not disturb the existence of other effects. One embodiment of the present invention does not necessarily achieve all the objects listed above. Other effects will be apparent from and can be derived from the description of the specification, the drawings, the claims, and the like.

### BRIEF DESCRIPTION OF THE DRAWINGS

In the accompanying drawings:

FIGS. 1A and 1B illustrate structures of a film formation apparatus of an embodiment;

FIGS. 2A to 2C illustrate structures of shadow masks of an embodiment;

FIGS. 3A and 3B illustrate structures of shadow masks of an embodiment;

FIGS. 4A to 4C illustrate structures of shadow masks of an embodiment;

FIG. 5 is a flowchart showing a film formation method and a cleaning method of an embodiment;

FIGS. 6A and 6B illustrate structures of film formation systems of an embodiment;

FIGS. 7A to 7D illustrate structures of light-emitting elements of an embodiment;

FIGS. 8A to 8D illustrate structures of a display device of an embodiment;

FIGS. 9A to 9D illustrate structures of a display device of an embodiment;

FIGS. 10A1, 10A2, 10A3, 10B1, 10B2, 10C1, and 10C2 are projection views illustrating structures of information processing devices of an embodiment;

FIGS. 11A and 11B illustrate structures of a shadow mask of an embodiment;

FIGS. 12A and 12B illustrate structures of a shadow mask of an embodiment;

FIGS. 13A and 13B illustrate structures of a shadow mask of an embodiment;

FIGS. 14A and 14B illustrate structures of a shadow mask of an embodiment;

FIGS. 15A to 15C illustrate structures of shadow masks of an embodiment; and

FIGS. 16A to 16C illustrate structures of shadow masks of an embodiment.

### DETAILED DESCRIPTION OF THE INVENTION

A film formation apparatus of one embodiment of the present invention includes a film formation chamber and an adhesive layer that is on the inner wall of the film formation chamber and to which a film formation material is to be attached.

This allows suppression of dust generated from the film formation material attached to the inner wall of the film formation chamber. As a result, a novel film formation apparatus can be provided. Alternatively, a novel shadow mask can be provided. Alternatively, a novel film formation method can be provided. Alternatively, a novel cleaning method can be provided.

Embodiments will be described in detail with reference to drawings. Note that the present invention is not limited to the description below, and it is easily understood by those skilled in the art that various changes and modifications can be made without departing from the spirit and scope of the present invention. Accordingly, the present invention should not be interpreted as being limited to the content of the embodiments below. Note that in the structures of the invention described below, the same portions or portions having similar functions are denoted by the same reference numerals in different drawings, and the description of such portions is not repeated.

### Embodiment 1

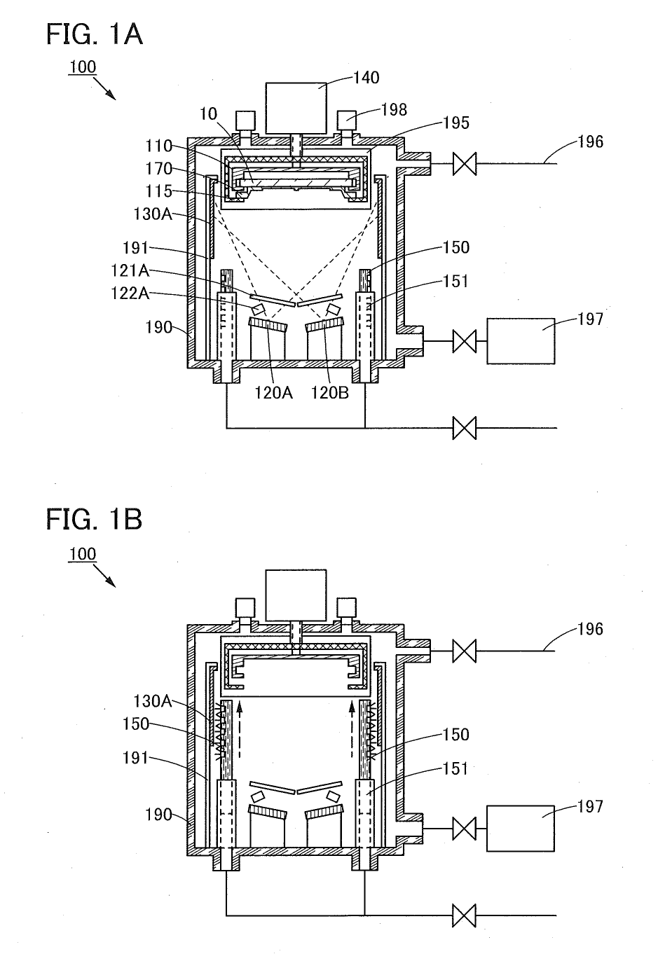

In this embodiment, a structure of a film formation apparatus of one embodiment of the present invention will be described with reference to FIGS. 1A and 1B, FIGS. 2A to 2C, and FIG. 4A.

FIGS. 1A and 1B illustrate the structure of the film formation apparatus of one embodiment of the present invention. FIG. 1A is a cross-sectional view showing a state in which a film is formed on a processed member 10 with use of a film formation apparatus 100 and a shadow mask 170 of one embodiment of the present invention. FIG. 1B is a cross-sectional view showing a state in which a film formation chamber 190 is cleaned in the film formation apparatus 100.

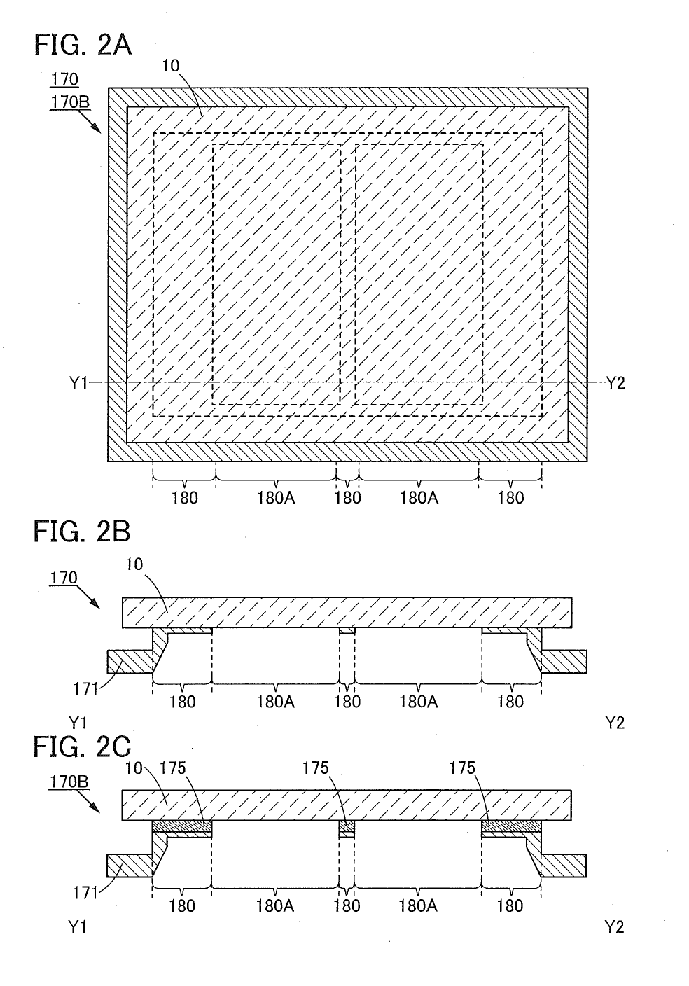

FIGS. 2A to 2C illustrate the shadow mask 170 of one embodiment of the present invention and the processed member 10. FIG. 2A is a top view of the shadow mask 170 of one embodiment of the present invention and the processed member 10, and FIG. 2B is a cross-sectional view along a section line Y1-Y2 in FIG. 2A.

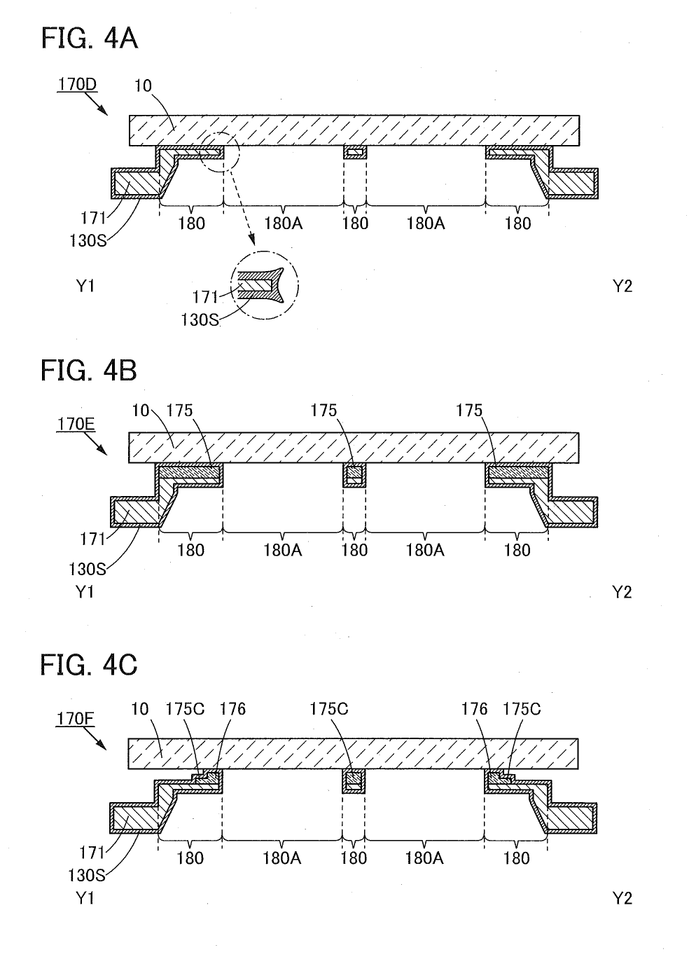

FIG. 4A is a cross-sectional view of the shadow mask 170 coated with an adhesive layer 130S.

### <Structure Example 1 of Film Formation Apparatus>

The film formation apparatus 100 shown in this embodiment includes a processed member support 110 configured to support the processed member 10, an evaporation source 120A configured to eject a film formation material that is to be attached to the processed member 10, an adhesive layer 130A to which the film formation material is to be attached, and the film formation chamber 190 including the processed member support 110, the evaporation source 120A, and the adhesive layer 130A (see FIG. 1A).

The adhesive layer 130A includes a region facing the evaporation source 120A. For example, the adhesive layer 130A is provided on the inner wall of the film formation chamber 190 that faces the evaporation source 120A.

The film formation apparatus 100 shown in this embodiment includes the film formation chamber 190 and the adhesive layer 130A that is, for example, on the inner wall of the film formation chamber 190 and to which the film formation material is to be attached. This allows suppression of dust generated from the film formation material attached to the inner wall of the film formation chamber. As a result, a novel film formation apparatus can be provided.

### <Structure Example 2 of Film Formation Apparatus>

The film formation apparatus 100 shown in this embodiment includes the processed member support 110 configured to support the processed member 10, the evaporation source 120A configured to eject a film formation material that is to be attached to the processed member 10, a shadow mask support 115 which is between the processed member 10 and the evaporation source 120A and is configured to support the shadow mask 170, the adhesive layer 130S to which the film formation material is to be attached, and the film formation chamber 190 including the processed member support 110, the evaporation source 120A, the shadow mask support 115, and the adhesive layer 130S (see FIG. 1A).

The adhesive layer 130S is provided on the shadow mask 170 so as to have a region facing the evaporation source 120A (see FIG. 4A).

In the film formation apparatus 100 shown in this embodiment, the adhesive layer 130S to which the film formation material is attached is on the evaporation source 120A side of the shadow mask 170. This allows suppression of dust generated from the film formation material attached to the evaporation source side of the shadow mask. As a result, a novel film formation apparatus can be provided.

### <Structure Example 3 of Film Formation Apparatus>

In the film formation apparatus 100 shown in this embodiment, the adhesive layer 130A or the adhesive layer 130S has an adhesion strength of 1 N to 20 N (in a 25-mm-wide sample).

In the film formation apparatus 100 shown in this embodiment, a material having an adhesion strength of 1 N to 20 N in a 25-mm-wide sample is used for the adhesive layer 130A or the adhesive layer 130S. This allows suppression of removal of the film formation material attached to the adhesive layer from the adhesive layer and suppression of dust generated from the film formation material attached to the adhesive layer. As a result, a novel film formation apparatus can be provided.

### <Structure Example 4 of Film Formation Apparatus>

The film formation apparatus 100 shown in this embodiment includes a plasma source 150 from which plasma is delivered to the adhesive layer 130A, and a plasma source support 151 which supports the plasma source 150 and moves relatively to the adhesive layer 130A (see FIG. 1B).

The film formation apparatus shown in this embodiment includes the plasma source 150 from which plasma is delivered to the adhesive layer 130A. This allows removal of the film formation material attached to the adhesive layer and suppression of dust generated from the film formation material attached to the adhesive layer. As a result, a novel film formation apparatus can be provided.

In addition, the film formation apparatus 100 may include a power mechanism 140. For example, the film formation apparatus 100 may be configured to move the processed member support 110 and the processed member 10 relatively to the evaporation source 120A with use of the power mechanism 140. Accordingly, a film formation material ejected from the evaporation source 120A can be uniformly deposited on the surface of the processed member 10.

Further, in the film formation apparatus 100, the power mechanism 140 may be used to move the shadow mask support 115 together with the shadow mask 170, the processed member support 110, and the processed member 10.

Moreover, the film formation apparatus 100 may include a sensor 198 for sensing the position of the shadow mask 170 relative to the processed member 10. For example, the processed member 10 is arranged at a predetermined position relative to the shadow mask 170 by being transferred with the processed member support 110 or/and the shadow mask support 115.

The film formation apparatus 100 may also include an evacuation unit 197 for controlling the pressure in the film formation chamber 190 and a pipe 196 for introducing a predetermined gas into the film formation chamber 190.

Furthermore, the film formation apparatus 100 may include a door valve 195 configured to carry the processed member 10 or/and the shadow mask 170 in or/and out of the film formation chamber 190.

The film formation apparatus 100 may include an evacuation source 120B as well as the evaporation source 120A. Moreover, the film formation apparatus 100 may include a shielding plate 121A which shields a film formation material ejected from the evaporation source 120A, and a sensor 122A for measuring the amount of film formation material ejected from the evaporation source 120A per unit time.

Individual components included in the film formation apparatus 100 will be described below. Note that these units cannot be clearly distinguished and one unit also serves as another unit or include part of another unit in some cases.

### <<Overall Structure>>

The film formation apparatus 100 shown in this embodiment includes the processed member support 110, the shadow mask support 115, the evaporation source 120A, the adhesive layer 130A, the adhesive layer 130S, the film formation chamber 190, the plasma source 150, or the plasma source support 151.

### <<Processed Member Support 110>>

The processed member support 110 is configured to support the processed member 10. The processed member support 110 may also be configured to move the processed member 10 relatively to the evaporation source 120A.

For example, the processed member support 110 may have a structure holding or supporting an edge of the processed member 10 or the vicinity thereof. Specifically, a member provided with a clamp mechanism or a supporting member with an L shape or the like can be used. Alternatively, a plurality of structures holding or supporting the processed member 10 may be provided. Specifically, in the case where the processed member 10 has a rectangular shape, the four corners of the processed member 10 or the vicinity thereof may be supported.

The processed member support 110 can be moved relatively to the evaporation source 120A with use of, for example, the power mechanism 140. Specifically, a servomotor, a stepping motor, or an air cylinder may be used to move the processed member support 110. Specifically, the processed member support 110 may rotate over the evaporation source 120A or pass across the evaporation source 120A.

Note that the processed member support 110 may be configured to maintain the position of the processed member 10 relative to the shadow mask 170, e.g., closely attach the processed member 10 to the shadow mask 170. Specifically, the processed member 10 may be pressed against the shadow mask with use of an elastic body such as a spring. Alternatively, a magnet or the like may be provided so that the processed member 10 is interposed between the magnet and the shadow mask, thereby attracting the shadow mask towards the processed member 10.

There is no particular limitation on the material for the processed member 10 as long as the processed member 10 has heat resistance high enough to withstand a manufacturing process and a thickness and a size which can be used in a manufacturing apparatus.

In addition, the processed member 10 can include a variety of functional layers, e.g., a layer including a functional circuit, a functional element, an optical element, or a functional film or a layer including a plurality of components selected from these examples. Specific examples are a pixel circuit of a display device, a driver circuit of a pixel, a display element, a color filter, and a moisture-proof film that are publicly known; and a layer including a plurality of layers selected from the these examples.

For the processed member 10, an organic material, an inorganic material, a composite material of an organic material and an inorganic material, or the like can be used.

For example, an inorganic material such as glass, ceramic, or metal can be used for the processed member 10.

Specifically, non-alkali glass, soda-lime glass, potash glass, crystal glass, or the like can be used for the processed member 10.

Specifically, an inorganic oxide film, an inorganic nitride film, an inorganic oxynitride film, or the like can be used for the processed member 10. For example, a silicon oxide film, a silicon nitride film, a silicon oxynitride film, or an alumina film can be used for the processed member 10.

For example, an organic material such as a resin, a resin film, or plastic can be used for the processed member 10.

Specifically, a resin film or resin plate of polyester, polyolefin, polyamide, polyimide, polycarbonate, an acrylic resin, or the like can be used for the processed member 10.

For example, a composite material such as a resin film to which a thin glass plate or a film of an inorganic material is attached can be used for the processed member 10.

For example, a composite material formed by dispersing a fibrous or particulate metal, glass, inorganic material, or the like into a resin film can be used for the processed member 10.

For example, a composite material formed by dispersing a fibrous or particulate resin, organic material, or the like into an inorganic material can be used for the processed member 10.

Furthermore, a single-layer material or a stacked-layer material in which a plurality of layers are stacked can be used for the processed member 10. For example, a stacked-layer material in which a material, an insulating layer that prevents diffusion of impurities contained in the material, and the like are stacked can be used for the processed member 10.

Specifically, a stacked-layer material in which glass and one or a plurality of films that prevent diffusion of impurities contained in the glass and that are selected from a silicon oxide film, a silicon nitride film, a silicon oxynitride film, and the like are stacked can be used for the processed member 10.

### <<Shadow Mask Support 115>>

The shadow mask support 115 is configured to support the shadow mask 170. The shadow mask support 115 may also be configured to move the shadow mask relatively to the evaporation source 120A.

For example, the shadow mask support 115 may have a structure holding or supporting an edge of the shadow mask 170 or the vicinity thereof. Specifically, a member provided with a clamp mechanism or a supporting member with an L shape or the like can be used. Alternatively, a plurality of structures holding or supporting the shadow mask 170 may be provided. Specifically, in the case where the shadow mask 170 has a rectangular shape, the four corners of the shadow mask 170 or the vicinity thereof may be supported.

The shadow mask support 115 can be moved relatively to the evaporation source 120A with use of, for example, the power mechanism 140. Specifically, a servomotor, a stepping motor, or an air cylinder may be used to move the shadow mask support 115. Specifically, the shadow mask support 115 may rotate over the evaporation source 120A or pass across the evaporation source 120A.

### <<Shadow Mask 170>>

The shadow mask 170 includes a shielding region 180 configured to shield a film formation material and an opening region 180A surrounded by the shielding region 180. The shielding region 180 includes a base 171 (see FIGS. 2A and 2B). Note that the film formation material can pass through the opening region 180A. The film formation material ejected from the evaporation source 120A is shielded by the shadow mask 170 provided between the surface of the processed member 10 and the evaporation source 120A and cannot reach and be attached to the surface of the processed member 10. In addition, the film formation material is ejected from the evaporation source at various angles with respect to the surface of the processed member 10. Hence, the shape of a region that the shadow mask 170 prevents from an attachment of the film formation material is affected not only by the shape of the shadow mask 170 in a direction opposite to the processed member 10, but also by the shape of the shadow mask 170 in an oblique direction.

For example, the shadow mask 170 described in Embodiment 2 can be used.

### <<Evaporation Source>>

The film formation apparatus 100 includes one or more evaporation sources, e.g., the evaporation source 120A and the evaporation source 120B.

The same material can be ejected from the evaporation source 120A and the evaporation source 120B. This increases the thickness of the film formation material that is deposited on the surface of the processed member 10 per unit time.

Different materials may be ejected from the evaporation source 120A and the evaporation source 120B. As a result, a film including a mixture of the different materials can be formed on the surface of the processed member 10, i.e., co-evaporation can be carried out.

The evaporation source 120A is configured to eject a film formation material and preferably has directivity, for example, in the direction in which the film formation material is ejected. This increases the efficiency of use of the film formation material.

Specifically, a point evaporation source, a linear evaporation source, or the like can be used as the evaporation source 120A. Alternatively, it is possible to use an evaporation source in which point sources are arranged linearly or in a matrix, or an evaporation source from which a vaporized film formation material is ejected through a slit.

The film formation apparatus 100 may be configured to move the evaporation source 120A relatively to the processed member support 110. For example, film formation may be performed while the processed member 10 is moved relatively to the evaporation source 120A with use of a power mechanism.

### <<Adhesive Layer>>

Since a film formation material is to be attached to the adhesive layer 130A, the attached film formation material is unlikely to be removed.

For example, a material with a thickness of 2 mm or less, preferably 100 μm or less can be used for the adhesive layer 130A.

A variety of materials can be used for the adhesive layer 130A. Specifically, a resin such as polyester, a silicone resin, or an acrylic resin, elastomer, or the like can be used for the adhesive layer 130A.

Specifically, a material having an adhesion strength of 1 N to 20 N, preferably 3 N to 5 N in a 25-mm-wide sample can be used for the adhesive layer. A lower adhesion strength of the adhesive layer 130A reduces damage on a support (e.g., an attachment protection plate 191) that supports the adhesive layer 130A in peeling.

The adhesive layer 130A is provided on the inner wall of the film formation chamber 190 or on the attachment protection plate 191 so as to have a region facing the evaporation source 120A. Note that the attachment protection plate 191 is arranged between the evaporation source 120A and the inner wall of the film formation chamber 190.

The adhesive layer 130S is provided on the shadow mask 170 so as to have a region facing the evaporation source 120A.

The shape of a region that the shadow mask 170 prevents from an attachment of the film formation material is affected by the thickness of the adhesive layer 130S. Note that the adhesive layer 130S is preferably as thin as possible. For example, a material with a thickness of 2 mm or less, preferably 100 μm or less can be used for the adhesive layer 130S. For example, silicone rubber with an adhesion strength of 4 N in a 25-mm-wide sample can be used for the adhesive layer 130S.

Note that the adhesive layer can be formed by a variety of methods, e.g., a printing method, a spray method, an inkjet method, a dip coating method, an electric field coating method, or an ion plating method.

### <<Film Formation Chamber>>

The pressure in the film formation chamber 190 can be reduced to a mospheric pressure or lower, e.g., 10⁻³ Pa or lower.

The pressure in the film formation chamber 190 can be reduced with the evacuation unit 197. For example, a mechanical pump, a turbo pump, or/and a cryopump can be used as the evacuation unit 197.

The inside of the film formation chamber 190 can be filled with a gas. The pipe 196 can supply, for example, a nitrogen gas to the film formation chamber.

The film formation chamber 190 can be configured to heat the inner wall. This allows molecules adsorbed on the inner wall to be removed efficiently. For example, a heater, or a pipe supplied with a heating medium may be provided on the wall.

### <<Plasma Source 150>>

A gas is supplied to the plasma source 150 and converted into plasma, and the plasma can be delivered from the plasma source 150. In addition, the plasma source 150 is supported by the plasma source support 151.

For example, a gas to be supplied can be selected in accordance with the adhesive layer 130 and the film formation material attached to the adhesive layer 130. Further, the supplied gas can be converted into plasma to be delivered.

Specifically, it is possible to use a rare gas (e.g., argon, xenon, or helium), a reducing gas (e.g., hydrogen), an oxidizing gas (e.g., oxygen or nitrous oxide), a halide gas (e.g., carbon tetrafluoride), or a gas in which any of these gases are mixed as appropriate.

A structure (a remote plasma source) of supplying plasma generated far from a plasma irradiation region can also be employed; for example, a hollow cathode type can be employed. In that case, the plasma source can be provided outside of the film formation chamber 190.

In addition, a linear laser may be used as an auxiliary means. A film formation material attached to the adhesive layer 130 may be heated by plasma and removed from the adhesive layer 130.

The plasma source support 151 is configured to move the plasma source 150 relatively to the adhesive layer 130A.

For example, the plasma source 150 may be supported by the plasma source support 151 so as to be able to slide. Specifically, one end of a slider or a slider guide is fixed to the plasma source 150 and the other is fixed to the plasma source support 151.

When a film formation material is deposited, for example, the plasma source 150 is slid so as to have a large area overlapping with the plasma source support 151. This prevents the film formation material ejected from the evaporation source 120A from being shielded by the plasma source 150 involuntarily (see FIG. 1A).

When the attached film formation material is removed in cleaning, for example, the plasma source 150 is slid so as to have a small area overlapping with the plasma source support 151. As a result, the plasma source 150 can be made close to a portion to which the film formation material is attached (see FIG. 1B).

Note that this embodiment can be combined with any of the other embodiments in this specification as appropriate.

### Embodiment 2

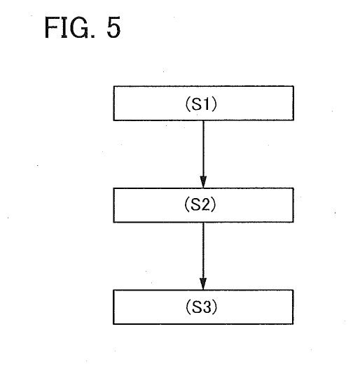

In this embodiment, structures of a film formation method and a cleaning method of one embodiment of the present invention will be described with reference to FIGS. 1A and 1B and FIG. 5.

FIG. 5 is a flowchart showing the film formation method and the cleaning method of one embodiment of the present invention.

### <Film Formation Method and Cleaning Method>

The film formation method and the cleaning method described in this embodiment have the following three steps and use the film formation apparatus 100 described in Embodiment 1.

### <<First Step>>

In a first step, the film formation chamber 190 is evacuated (see FIG. 5(S1)).

For example, the pressure in the film formation chamber 190 is reduced to 10⁻³ Pa or lower, preferably 10⁻⁴ Pa or lower with use of the evacuation unit 197 or the like.

Then, a film formation material is ejected from the evaporation source 120A at a predetermined rate. For example, heating is performed so that the ejection rate of the film formation material measured by the sensor 122A is a predetermined rate. Note that the film formation material ejected from the evaporation source is preferably shielded by the shielding plate 121A or the like, in which case the film formation material is not attached to a large area of the film formation chamber 190.

Next, the shadow mask 170 is carried in the film formation chamber 190 while the door valve 195 is opened. For example, the shadow mask 170 is delivered to the shadow mask support 115 with use of a transfer mechanism. Note that the shadow mask 170 may be set in the film formation chamber 190 in advance.

Next, the processed member 10 is carried in the film formation chamber 190 while the door valve 195 is opened. For example, the processed member 10 is delivered to the processed member support 110 with use of a transfer mechanism.

After that, the processed member 10 is arranged at a predetermined position relative to the shadow mask 170 by using the processed member support 110 or/and the shadow mask support 115. Note that the position of the processed member 10 relative to the shadow mask 170 can be detected by the sensor 198.

### <<Second Step>>

A film formation material is ejected to be deposited on the surface of the processed member 10 while being attached to the adhesive layer 130A (see FIG. 5(S2)).

For example, film formation is performed by controlling the period of time during which the film formation material is attached to the processed member 10. Specifically, the period of time can be controlled with use of the shielding plate 121A or the like. Alternatively, the rate at which the processed member 10 passes across the evaporation source 120A can be controlled by the processed member support 110 and the power mechanism 140.

Then, the processed member 10 on which a predetermined film is formed is carried out of the film formation chamber 190.

In the case where a film is formed on another processed member 10, the other processed member 10 is carried in and the above steps are repeated.

In the case where the film formation is completed, the ejection of the film formation material is stopped. Specifically, heating of the evaporation source 120A is stopped to decrease the temperature of the film formation material in the evaporation source 120A.

Then, the pressure in the film formation chamber 190 is adjusted. Specifically, the pressure is adjusted to be 0.1 Pa to 2000 Pa, preferably 1 Pa to 100 Pa with use of the evacuation unit 197 while a predetermined gas is introduced through the pipe 196.

### <<Third Step>>

Plasma is delivered from the plasma source 150 to the adhesive layer 130A to remove the film formation material (see FIG. 5(S3)).

Specifically, parallel-plate electrodes can be used which are arranged at an interval of, for example, 50 mm with the adhesive layer 130A interposed therebetween. The evacuation is performed to a pressure of 5 Pa while an Ar gas is supplied at a flow rate of 2000 sccm.

The film formation method and cleaning method shown in this embodiment include the step of depositing the film formation material on the surface of the processed member 10 while attaching the film formation material to the adhesive layer 130A, and the step of delivering plasma from the plasma source 150 to the adhesive layer 130A to remove the film formation material. This allows suppression of dust generated from the film formation material attached to the adhesive layer and removal of the film formation material attached to the adhesive layer with use of plasma. As a result, a novel film formation method and cleaning method can be provided.

Note that this embodiment can be combined with any of the other embodiments in this specification as appropriate.

### Embodiment 3

In this embodiment, structures of shadow masks of one embodiment of the present invention will be described with reference to FIGS. 2A to 2C, FIGS. 3A and 3B, and FIGS. 4A to 4C.

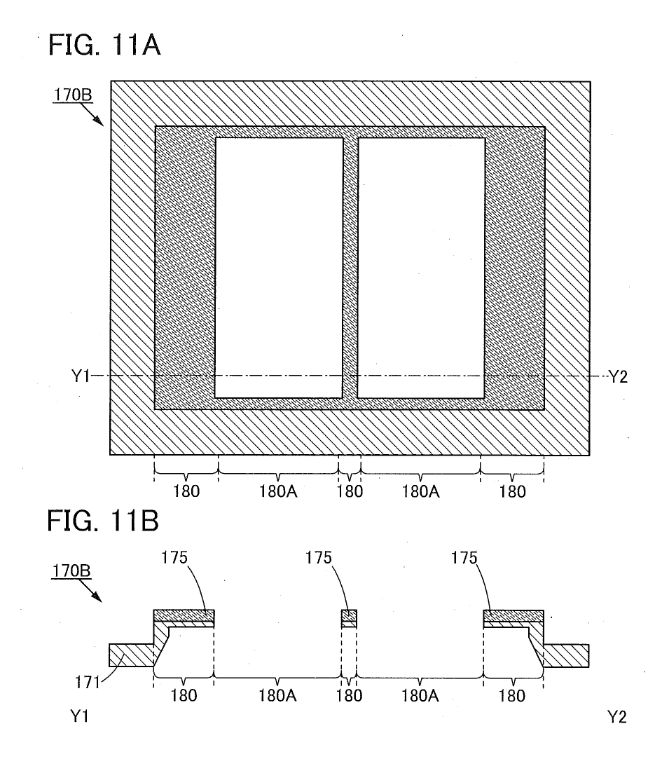

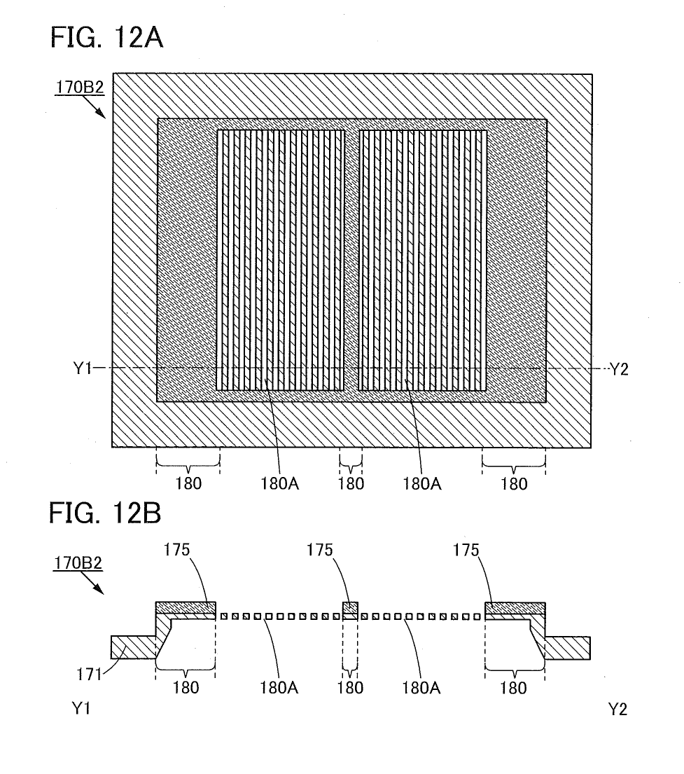

FIGS. 2A to 2C and FIGS. 11A and 11B illustrate a shadow mask 170B of one embodiment of the present invention and the processed member 10. FIG. 2A is a top view of the processed member 10 and the shadow mask 170B of one embodiment of the present invention, and FIG. 2C is a cross-sectional view of the processed member 10 and the shadow mask 170B along the section line Y1-Y2 in FIG. 2A. FIG. 11A is a top view of the shadow mask 170B of one embodiment of the present invention, and FIG. 11B is a cross-sectional view of the shadow mask 170B along a section line Y1-Y2 in FIG. 11A. FIGS. 12A and 12B illustrate a shadow mask 170B2 of one embodiment of the present invention. FIG. 12A is a top view of the shadow mask 170B2 of one embodiment of the present invention, and FIG. 12B is a cross-sectional view of the shadow mask 170B2 along a section line Y1-Y2 in FIG. 12A.

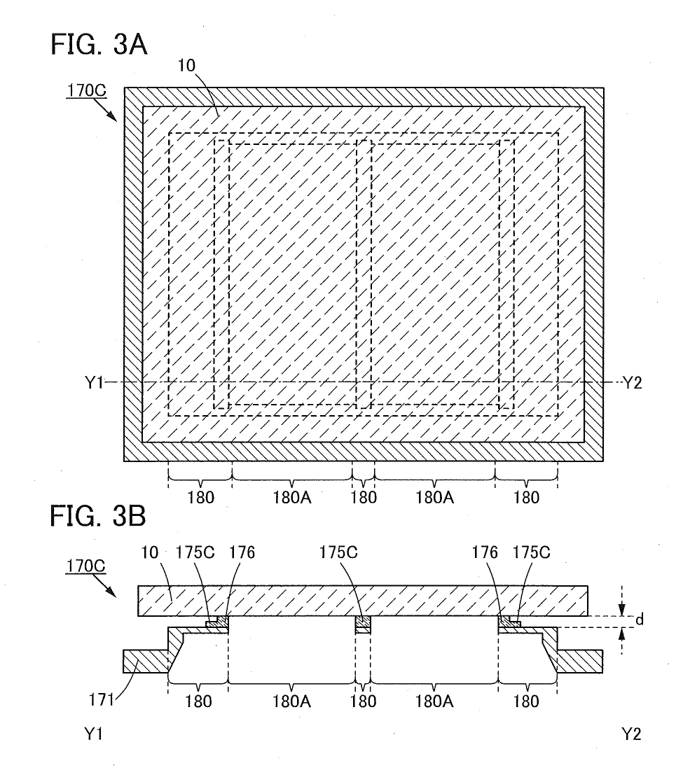

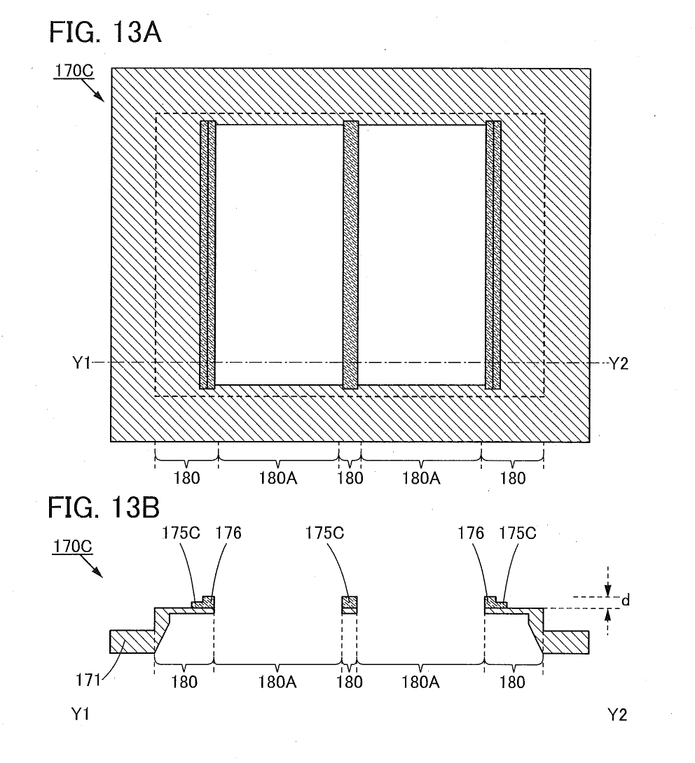

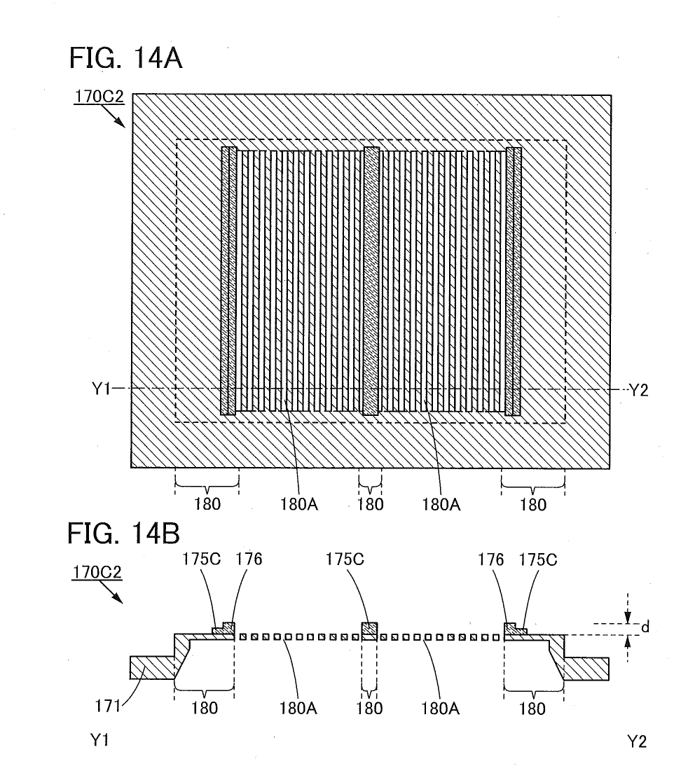

FIGS. 3A and 3B and FIGS. 13A and 13B illustrate a shadow mask 170C of one embodiment of the present invention and the processed member 10. FIG. 3A is a top view of the processed member 10 and the shadow mask 170C of one embodiment of the present invention, and FIG. 3B is a cross-sectional view of the shadow mask 170C along a section line Y1-Y2 in FIG. 3A. FIG. 13A is a top view of the shadow mask 170C of one embodiment of the present invention, and FIG. 13B is a cross-sectional view of the shadow mask 170C along a section line Y1-Y2 in FIG. 13A. FIGS. 14A and 14B illustrate a shadow mask 170C2 of one embodiment of the present invention. FIG. 14A is a top view of the shadow mask 170C2 of one embodiment of the present invention, and FIG. 14B is a cross-sectional view of the shadow mask 170C2 along a section line Y1-Y2 in FIG. 14A.

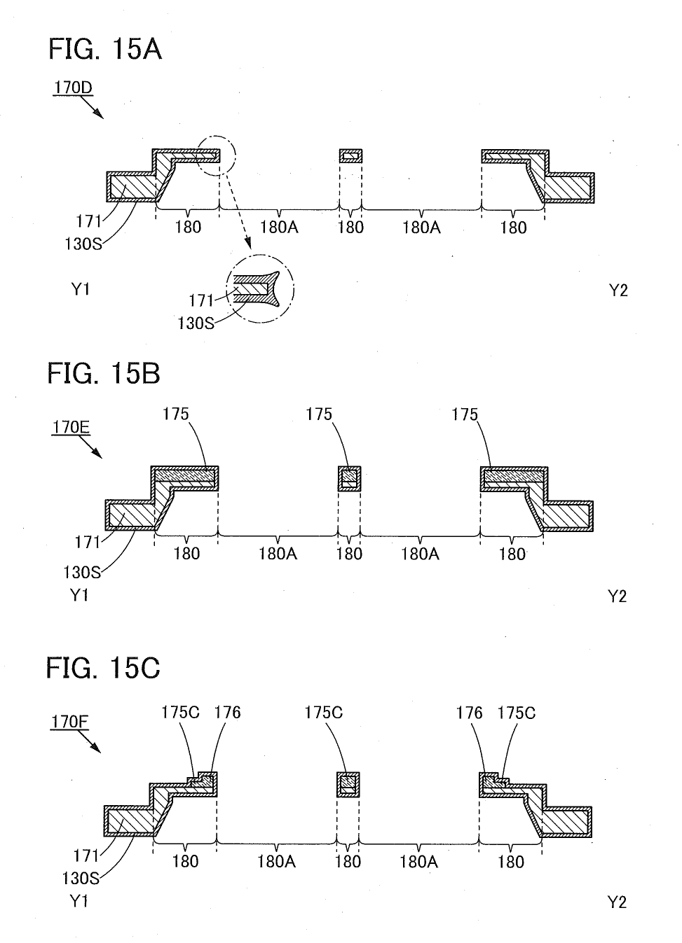

FIG. 4A and FIG. 15A are cross-sectional views of a shadow mask 170D provided with the adhesive layer 130S. FIG. 4B and FIG. 15B are cross-sectional views of a shadow mask 170E provided with the adhesive layer 130S. FIG. 4C and FIG. 15C are cross-sectional views of a shadow mask 170F provided with the adhesive layer 130S.

### <Structure Example 1 of Shadow Mask>

The shadow mask 170B shown in this embodiment includes the shielding region 180 configured to shield a film formation material and the opening region 180A surrounded by the shielding region 180. The shielding region 180 includes the base 171 and a resin layer 175 in contact with the base 171. The resin layer 175 is configured to be separated from the base 171 (see FIG. 2C).

The shadow mask 170B shown in this embodiment includes the base 171 and the resin layer 175 that can be separated from the base 171 and is on the side of the base 171 that is in contact with the processed member 10. Accordingly, for example, dust attached to the processed member 10 can be transferred to the resin layer 175 to be removed. Moreover, dust transferred to the resin layer 175 can also be separated from the base 171 along with the resin layer 175. As a result, a novel shadow mask can be provided.

Individual components included in the shadow mask 170B will be described below. Note that these units cannot be clearly distinguished and one unit also serves as another unit or include part of another unit in some cases.

### <<Overall Structure>>

The shadow mask 170B shown in this embodiment includes the base 171, the shielding region 180, the opening region 180A, or the resin layer 175.

### <<Base 171>>

There is no particular limitation on the material for the base 171 as long as the base 171 has heat resistance high enough to withstand a film formation process and a thickness and a size which can be used in a film formation apparatus. The base 171 includes the shielding region 180 and the opening region 180A.

A single member or a combination of plural members can be used for the base 171. For example, a thin member may be used for the shielding region 180 and a member with high rigidity may be used for a part supporting the shielding region 180.

For the base 171, an organic material, an inorganic material, a composite material of an organic material and an inorganic material, or the like can be used.

For example, an inorganic material such as metal or ceramic can be used for the base 171.

Specifically, an alloy containing aluminum, an alloy containing iron, an alloy containing nickel, SUS, invar, or the like can be used for the base 171.

Specifically, an inorganic oxide film, an inorganic nitride film, an inorganic oxynitride film, or the like can be used for the base 171. For example, a silicon oxide film, a silicon nitride film, a silicon oxynitride film, or an alumina film can be used for the base 171.

For example, an organic material such as a resin or plastic can be used for the base 171.

Specifically, a resin such as polyester, polyolefin, polyamide, polyimide, polycarbonate, or an acrylic resin can be used for the base 171.

For example, a composite material formed by dispersing a fibrous or particulate metal, inorganic material, or the like into a resin can be used for the base 171.

For example, a composite material formed by dispersing a fibrous or particulate resin, organic material, or the like into an inorganic material can be used for the base 171.

Furthermore, a single-layer material or a stacked-layer material in which a plurality of layers are stacked can be used for the base 171. For example, a stacked-layer material in which a material, an insulating layer that prevents diffusion of impurities contained in the material, and the like are stacked can be used for the base 171.

### <<Shielding Region 180 and Opening Region 180A>>

The thickness of the thinnest part of the shielding region 180 is less than the narrowest width of the opening region 180A, and is specifically 1 mm or less, preferably 200 μm or less, and further preferably 50 μm or less. As the thickness of the shielding region 180 decreases, the width of the opening region 180A can be reduced.

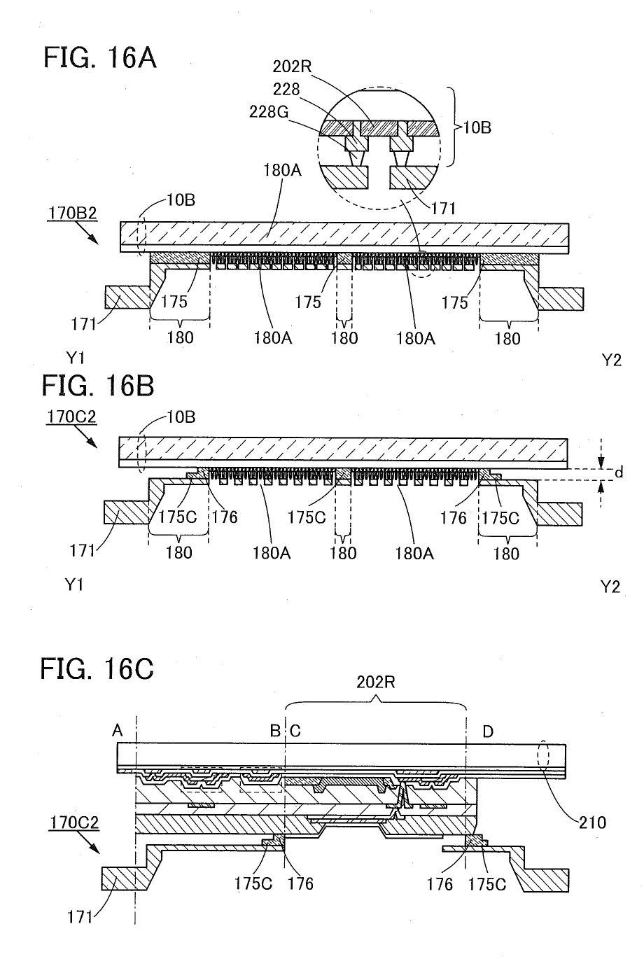

The opening region 180A can have a variety of shapes, e.g., a square, a rectangle, a polygon, or a circle. The area of the opening region 180A can be, for example, 1200 μm² or more, preferably 27 cm² or more, preferably 50 cm² or more, preferably 190 cm² or more, preferably 1500 cm² or more, and further preferably 5000 cm² or more. Note that the width of the opening region 180A in the shadow mask 170B2 of one embodiment of the present invention illustrated in FIGS. 12A and 12B is narrower than that of the opening region 180A in the shadow mask 170B. FIG. 16A illustrates a method of forming a film on a subpixel 202R on the processed member 10B with use of the shadow mask 170B2. The use of the shadow mask 170B2 enables a film to be formed while pixels adjacent to the subpixel 202R are covered. Note that the processed member 10B includes a partition wall 228 surrounding the subpixel 202R and a resin layer 228G on the partition wall 228. The resin layer 228G is in contact with the base 171 of the shadow mask 170B2 and is configured to determine the position of the shadow mask 170B2 relative to the processed member 10B.

<<Resin Layer 175>>

The resin layer 175 is provided in the shielding region 180 adjacent to the opening region 180A.

The shape of a region that the shadow mask 170 prevents from an attachment of the film formation material is affected by the thickness of the resin layer 175. Note that the resin layer 175 is preferably as thin as possible. For example, a material with a thickness of 1 μm to 2 mm, preferably 30 μm to 100 μm can be used for the resin layer 175.

A variety of materials can be used for the resin layer 175. Specifically, a resin such as polyester, polyolefin, polyamide, polyimide, polycarbonate, a silicone resin, or an acrylic resin, elastomer, or the like can be used for the resin layer 175.

Specifically, a material having an adhesion strength of 1 N to 20 N, preferably 3 N to 5 N in a 25-mm-wide sample can be used for the resin layer 175. A lower adhesion strength of the resin layer 175 reduces damage on a support in peeling.

For example, silicone rubber with an adhesion strength of 4 N in a 25-mm-wide sample can be used for the resin layer 175.

The resin layer 175 is configured to be separated from the base 171.

For example, the resin layer 175 can be formed using a material that can be removed with a solvent or a cleaner. Specifically, a water-soluble material can be used for the resin layer 175. This allows the film formation material attached to the shadow mask to be removed without use of an organic solvent. As a result, a shadow mask that can be managed safely at low costs can be provided.

For example, the resin layer 175 can be formed using a material whose breaking strength is higher than the adhesion strength thereof. This allows the resin layer 175 to be peeled off without a residue remaining on the shadow mask.

For example, silicone rubber can be used for the resin layer 175.

### <Structure Example 2 of Shadow Mask>

Another structure of the shadow mask of one embodiment of the present invention will be described with reference to FIGS. 3A and 3B. Note that the width of the opening region 180A in the shadow mask 170C2 of one embodiment of the present invention illustrated in FIGS. 14A and 14B is narrower than that of the opening region 180A in the shadow mask 170C. FIG. 16B illustrates a method of forming a film on the subpixel 202R on the processed member 10B with use of the shadow mask 170C2. The use of the shadow mask 170C2 enables a film to be formed while pixels adjacent to the subpixel 202R are covered. FIG. 16C illustrates a method of forming a film on the subpixel 202R on the base 210 with use of the shadow mask 170C2.

Note that the shadow mask 170C is different from the shadow mask 170B described with reference to FIG. 2C in including the resin layer 175C provided with a protruding part 176. Different structures will be described in detail below, and the above description is referred to for the other similar structures.

In the shadow mask 170C shown in this embodiment, for example, the area of a part in contact with the processed member can be reduced to be equal to the area of the protruding part, so that dust attached to the shielding region is unlikely to be transferred to the processed member by contact. As a result, a novel shadow mask can be provided.

### <<Protruding Part>>

The resin layer 175C includes the protruding part 176. The protruding part 176 is adjacent to the opening region 180A. Alternatively, the protruding part 176 is narrower than the shielding region 180. Alternatively, the protruding part 176 is higher than the other parts by 5 μm or more, preferably 10 μm or more, and further preferably 20 μm or more. The height of the protruding part 176 is preferably 10 μm or more, which is larger than the size of possible attached dust. Note that the height of the protruding part is denoted by d in FIG. 3B.

The shadow mask 170C includes a protruding part in the area greater than or equal to 0.01% and less than 100%, preferably greater than or equal to 0.05% and less than or equal to 1% of the area of the shielding region 180. As the area including the protruding part is smaller, for example, the area of the protruding part that is in contact with the processed member 10 can be reduced. As area including the protruding part is larger, the shielding region can be more rigid. Specifically, the width of the protruding part can be 100 μm.

### <Structure Example 3 of Shadow Mask>

Another structure of the shadow mask of one embodiment of the present invention will be described with reference to FIGS. 4A and 15A.

The shadow mask 170D shown in this embodiment includes the shielding region 180 configured to shield a film formation material and the opening region 180A surrounded by the shielding region 180. The adhesive layer 130S is provided on the surface of the shielding region 180 (see FIG. 4A). Note that the adhesive layer 130S formed at a corner of the shielding region 180 has an acute angle in the cross section as indicated by a circle in the drawing.

The aforementioned shadow mask 170D of one embodiment of the present invention includes the adhesive layer 130S that is on the surface of the shielding region 180 and to which the film formation material is to be attached. This allows suppression of dust generated from the film formation material attached to the shadow mask. As a result, a novel shadow mask can be provided.

Note that the shadow mask 170D is different from the shadow mask 170 described with reference to FIG. 2B in that the adhesive layer 130S to which the film formation material is to be attached is provided on the surface of the shielding region 180. Different structures will be described in detail below, and the above description is referred to for the other similar structures.

### <<Adhesive Layer>>

Since a film formation material is to be attached to the adhesive layer 130S, the attached film formation material is unlikely to be removed.

The shape of a region that the shadow mask 170 prevents from an attachment of the film formation material is affected by the thickness of the adhesive layer 130S. Note that the adhesive layer 130S is preferably as thin as possible. For example, a material with a thickness of 2 mm or less, preferably 100 μm or less can be used for the adhesive layer 130S.

A variety of materials can be used for the adhesive layer 130S. Specifically, a resin such as polyester, a silicone resin, or an acrylic resin, elastomer, or the like can be used for the adhesive layer 130S.

Specifically, a material having an adhesion strength of 1 N to 20 N, preferably 3 N to 5 N in a 25-mm-wide sample can be used for the adhesive layer. A lower adhesion strength of the adhesive layer 130S reduces damage on the base 171 in peeling.

For example, silicone rubber with an adhesion strength of 4 N in a 25-mm-wide sample can be used for the adhesive layer 130S.

Note that the adhesive layer can be formed by a variety of methods, e.g., a printing method, a spray method, an inkjet method, a dip coating method, an electric field method, or an ion plating method.

### <Structure Example 4 of Shadow Mask>

Another structure of the shadow mask of one embodiment of the present invention will be described with reference to FIGS. 4B and 15B.

The shadow mask 170E shown in this embodiment is different from the shadow mask 170B described with reference to FIG. 2C in that the adhesive layer 130S to which the film formation material is to be attached is provided on the surface of the shielding region 180 on which the resin layer 175 is provided.

### <Structure Example 5 of Shadow Mask>

Another structure of the shadow mask of one embodiment of the present invention will be described with reference to FIGS. 4C and 15C.

The shadow mask 170F shown in this embodiment is different from the shadow mask 170C described with reference to FIG. 3B in that the adhesive layer 130S to which the film formation material is to be attached is provided on the surface of the shielding region 180 on which the resin layer 175C having a protruding part adjacent to an opening is provided.

Note that this embodiment can be combined with any of the other embodiments in this specification as appropriate.

### Embodiment 4

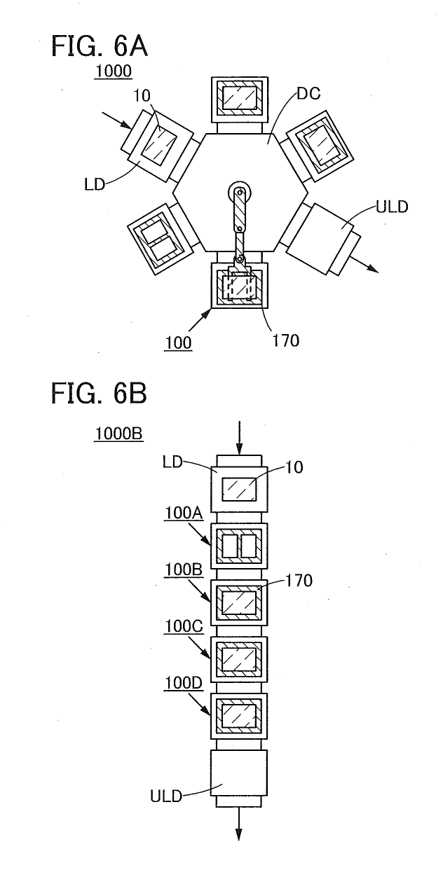

In this embodiment, structures of film formation systems of one embodiment of the present invention will be described with reference to FIGS. 6A and 6B.

FIGS. 6A and 6B illustrate the film formation systems of one embodiment of the present invention. FIG. 6A is a schematic view of a cluster film formation system 1000 and FIG. 6B is a schematic view of an in-line film formation system 1000B.

### <Structure Example 1 of Film Formation System>

The film formation system 1000 includes a loading unit LD, a transfer chamber DC connected to the loading unit LD, an unloading unit ULD connected to the transfer chamber DC, and the film formation apparatus 100 connected to the transfer chamber DC (see FIG. 6A).

The processed member 10 is carried in the loading unit LD to the transfer chamber DC and transferred therein. The processed member 10 is carried out of the unloading unit ULD. In addition, the processed member 10 is transferred to the film formation apparatus and a an formation material is deposited on the processed member 10.

The film formation apparatus 100 includes a transfer door. The shadow mask 170 is also carried in the film formation apparatus 100.

Note that a plurality of film formation apparatuses may be connected to the transfer chamber DC.

### <Structure Example 2 of Film Formation System>

The film formation system 1000B includes the loading unit LD, a film formation apparatus 100A connected to the loading unit LD, a film formation apparatus 100B connected to the film formation apparatus 100A, a film formation apparatus 100C connected to the film formation apparatus 100B, a film formation apparatus 100D connected to the film formation apparatus 100C, and the unloading unit ULD connected to the film formation apparatus 100D (see FIG. 6B).

The processed member 10 is carried in the loading unit LD, and then in the film formation apparatuses 100A to 100D. A film formation material is deposited on the processed member 10 and the processed member 10 is transferred. The processed member 10 is carried out of the unloading unit ULD.

The film formation apparatuses 100A to 100D each include a carry-in door and a carry-out door. The shadow mask 170 is carried in the film formation apparatuses 100A to 100D.

The above film formation system of the present invention includes a plurality of film formation apparatuses. Accordingly, a plurality of films can be stacked on the processed member 10. Furthermore, a film formation material can be stacked on a previously formed film without exposure of the film to the air.

Note that this embodiment can be combined with any of the other embodiments in this specification as appropriate.

### Embodiment 5

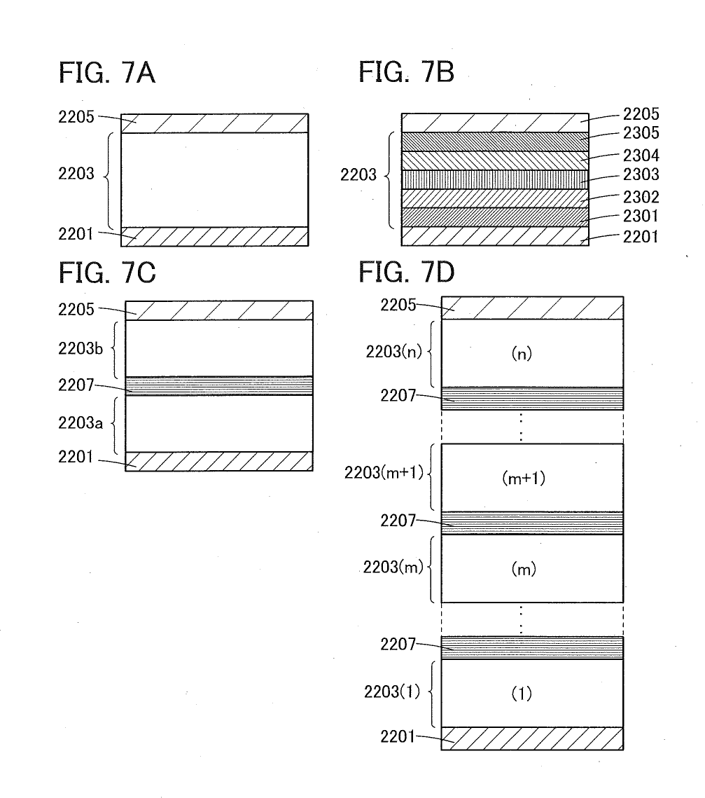

In this embodiment, light-emitting elements that can be manufactured with use of the film formation apparatus of one embodiment of the present invention will be described with reference to FIGS. 7A to 7D.

A light-emitting element illustrated in FIG. 7A includes an EL layer 2203 between a first electrode 2201 and a second electrode 2205. In this embodiment, the first electrode 2201 serves as the anode, and the second electrode 2205 serves as the cathode.

When a voltage higher than the threshold voltage of the light-emitting element is applied between the first electrode 2201 and the second electrode 2205, holes are injected to the EL layer 2203 from the first electrode 2201 side and electrons are injected to the EL layer 2203 from the second electrode 2205 side. The injected electrons and holes are recombined in the EL layer 2203 and a light-emitting organic compound contained in the EL layer 2203 emits light.

The EL layer 2203 includes at least a light-emitting layer 2303 containing a light-emitting organic compound.

In addition to the light-emitting layer 2303, the EL layer 2203 may further include one or more layers containing any of a substance with a high hole-injection property, a substance with a high hole-transport property, a substance with a high electron-transport property, a substance with a high electron-injection property, a substance with a bipolar property (a substance with a high electron-transport property and a high hole-transport property), and the like. For the EL layer 2203, either a low molecular compound or a high molecular compound can be used, and an inorganic compound may also be used.

A light-emitting element illustrated in FIG. 7B includes the EL layer 2203 between the first electrode 2201 and the second electrode 2205, and in the EL layer 2203, a hole-injection layer 2301, a hole-transport layer 2302, the light-emitting layer 2303, an electron-transport layer 2304, and an electron-injection layer 2305 are stacked in this order from the first electrode 2201 side.

As in light-emitting elements illustrated in FIGS. 7C and 7D, a plurality of EL layers may be stacked between the first electrode 2201 and the second electrode 2205. In that case, an intermediate layer 2207 is preferably provided between the stacked EL layers. The intermediate layer 2207 includes at least a charge-generation region.

For example, the light-emitting element illustrated in FIG. 7C includes the intermediate layer 2207 between a first EL layer 2203a and a second EL layer 2203b. The light-emitting element illustrated in FIG. 7D includes n EL layers 2203(1) to 2203(n) (n is a natural number of 2 or more), and the intermediate layers 2207 between the EL layers.

The behaviors of electrons and holes in the intermediate layer 2207 provided between the EL layer 2203(m) and the EL layer 2203(m+1) are described below. When a voltage higher than the threshold voltage of the light-emitting element is applied between the first electrode 2201 and the second electrode 2205, holes and electrons are generated in the intermediate layer 2207, and the holes move into the EL layer 2203(m+1) provided on the second electrode 2205 side and the electrons move into the EL layer 2203(m) provided on the first electrode 2201 side. The holes injected into the EL layer 2203(m+1) are recombined with the electrons injected from the second electrode 2205 side, so that a light-emitting organic compound contained in the EL layer 2203(m+1) emits light. The electrons injected into the EL layer 2203(m) are recombined with the holes injected from the first electrode 2201 side, so that a light-emitting organic compound contained in the EL layer 2203(m) emits light. Thus, the holes and electrons generated in the intermediate layer 2207 cause light emission in the respective EL layers.

Note that the EL layers can be provided in contact with each other without intermediate layer therebetween when the contact of these EL layers allows the formation of the same structure as the intermediate layer. Alternatively, when the charge-generation region is formed over one surface of an EL layer, another EL layer can be provided in contact with the surface.

When the EL layers have different emission colors, a desired emission color can be obtained from the whole light-emitting element. For example, in the light-emitting element having two EL layers, when an emission color of the first EL layer and an emission color of the second EL layer are made to be complementary colors, a light-emitting element emitting white light as a whole light-emitting element can also be obtained. This can be applied to a light-emitting element including three or more EL layers.

### <Material for Light-Emitting Element>

Examples of materials that can be used for the layers are given below. Note that each layer is not limited to a single layer and may be a stack of two or more layers.

### <<Anode>>

The electrode serving as the anode (the first electrode 2201) can be formed using one or more kinds of conductive metals, alloys, conductive compounds, and the like. In particular, it is preferable to use a material with a high work function (4.0 eV or more). Examples include ITO, indium tin oxide containing silicon or silicon oxide, indium zinc oxide, indium oxide containing tungsten oxide and zinc oxide, graphene, gold, platinum, nickel, tungsten, chromium, molybdenum, iron, cobalt, copper, palladium, and a nitride of a metal (e.g., titanium nitride).

When the anode is in contact with the charge-generation region, any of a variety of conductive materials can be used regardless of their work functions; for example, aluminum, silver, or an alloy containing aluminum can be used.

### <<Cathode>>

The electrode serving as the cathode (the second electrode 2205) can be formed using one or more kinds of conductive metals, alloys, conductive compounds, and the like. In particular, it is preferable to use a material with a low work function (3.8 eV or less). Examples include aluminum, silver, an element belonging to Group 1 or 2 of the periodic table (e.g., an alkali metal such as lithium or cesium, an alkaline earth metal such as calcium or strontium, or magnesium), an alloy containing any of these elements (e.g., Mg—Ag or Al—Li), a rare earth metal such as europium or ytterbium, and an alloy containing any of these rare earth metals.

Note that when the cathode is in contact with the charge-generation region, a variety of conductive materials can be used regardless of its work function. For example, ITO, or indium tin oxide containing silicon or silicon oxide can be used.

The electrodes may be formed separately by a vacuum evaporation method or a sputtering method. Alternatively, when a silver paste or the like is used, a coating method or an inkjet method may be used.

### <<Hole-Injection Layer 2301>>

The hole-injection layer 2301 contains a substance with a high hole-injection property.

Examples of the substance with a high hole-injection property include metal oxides such as molybdenum oxide, vanadium oxide, ruthenium oxide, tungsten oxide, and manganese oxide; and phthalocyanine-based compounds such as phthalocyanine (abbreviation: H₂Pc) and copper(II) phthalocyanine (abbreviation: CuPc).

Other examples of the substance with a high hole-injection property include high molecular compounds such as poly(N-vinylcarbazole) (abbreviation: PVK) or poly(4-vinyltriphenylamine) (abbreviation: PVTPA); and an acid-doped high molecular compound such as poly(3,4-ethylenedioxythiophene)/poly(styrenesulfonic acid) (PEDOT/PSS).

The hole-injection layer 2301 may serve as the charge-generation region. In this case, a variety of conductive materials can be used for the anode regardless of their work functions. Materials contained in the charge-generation region are described below.

### <<Hole-Transport Layer 2302>>

The hole-transport layer 2302 contains a substance with a high hole-transport property.

A substance transporting more holes than electrons is preferable as a substance with a high hole transport property, and a substance with a hole mobility of 10⁻⁶ cm²/Vs or more is especially preferable. A variety of compounds can be used as follows: an aromatic amine compound such as 4,4′-bis[N-(1-naphthyl)-N-phenylamino]biphenyl (abbreviation: NPB or α-NPD) or 4-phenyl-4′-(9-phenylfluoren-9-yl)triphenylamine (abbreviation: BPAFLP); a carbazole derivative such as 4,4′-di(N-carbazolyl)biphenyl (abbreviation: CBP), 9-[4-(10-phenyl-9-anthracenyl)phenyl]-9H-carbazole (abbreviation: CzPA), or 9-phenyl-3-[4-(10-phenyl-9-anthryl)phenyl]-9H-carbazole (abbreviation: PCzPA); an aromatic hydrocarbon compound such as 2-tert-butyl-9,10-di(2-naphthyl)anthracene (abbreviation: t-BuDNA), 9,10-di(2-naphthyl)anthracene (abbreviation: DNA), or 9,10-diphenylanthracene (abbreviation: DPAnth); a high molecular compound such as PVK or PVTPA, or the like.

### <<Light-Emitting Layer 2303>>

For the light-emitting organic compound included in the light-emitting layer 2303, a fluorescent compound or a phosphorescent compound can be used.

Examples of the fluorescent compound include N,N′-bis[4-(9H-carbazol-9-yl)phenyl]-N,N-diphenylstilbene-4,4′-diamine (abbreviation: YGA2S), N-(9,10-diphenyl-2-anthryl)-N,9-diphenyl-9H-carbazol-3-amine (abbreviation: 2PCAPA), and rubrene.

Examples of the phosphorescent compound include organometallic complexes such as bis[2-(4′,6′-difluorophenyl)pyridinato-N,C²′]iridium(III) picolinate (abbreviation: FIrpic), tris(2-phenylpyridinato-N,C²′)iridium(III) (abbreviation: Ir(ppy)₃), and (acetylacetonato)bis(3,5-dimethyl-2-phenylpyrazinato)iridium(III) (abbreviation: Ir(mppr-Me)₂(acac)).

The light-emitting layer 2303 may have a structure in which any of the above-described light-emitting organic compounds is dispersed as a guest material in another substance (a host material). As the host material, various kinds of materials can be used, and it is preferable to use a substance that has a lowest unoccupied molecular orbital level (LUMO level) higher than that of the guest material and has a highest occupied molecular orbital level (HOMO level) lower than that of the guest material.

With this structure, crystallization of the light-emitting layer 2303 can be suppressed. In addition, concentration quenching due to high concentration of the guest material can be suppressed.

As the host material, the above-described substance with a high hole-transport property (e.g., an aromatic amine compound or a carbazole derivative) or a later-described substance with a high electron-transport property (e.g., a metal complex having a quinoline skeleton or a benzoquinoline skeleton or a metal complex having an oxazole-based or thiazole-based ligand) can be used. As the host material, specifically, a metal complex such as tris(8-quinolinolato)aluminum(III) (abbreviation: Alq) or bis(2-methyl-8-quinolinolato) (4-phenylphenolato)aluminum(III) (abbreviation: BAlq); a heterocyclic compound such as 3-(4-biphenylyl)-4-phenyl-5-(4-tert-butylphenyl)-1,2,4-triazole (abbreviation: TAZ), bathophenanthroline (abbreviation: BPhen), or bathocuproine (abbreviation: BCP); a condensed aromatic compound such as CzPA, DNA, t-BuDNA, or DPAnth; or an aromatic amine compound such as NPB can be used.

Alternatively, as the host material, a plurality of kinds of materials can be used. For example, in order to suppress crystallization, a substance such as rubrene that suppresses crystallization may be further added. In addition, NPB, Alq, or the like may be further added in order to transfer energy to the guest material more efficiently.

When a plurality of light-emitting layers are provided and emission colors of the layers are made different, light emission of a desired color can be obtained from the light-emitting element as a whole. For example, in a light-emitting element having two light-emitting layers, the emission colors of first and second light-emitting layers are complementary, so that the light-emitting element can emit white light as a whole. This can be applied to a light-emitting element including three or more light-emitting layers.

### <<Electron-Transport Layer 2304>>

The electron-transport layer 2304 contains a substance with a high electron-transport property.

A substance transporting more electrons than holes is preferable as a substance with a high electron transport property, and a substance with an electron mobility of 10⁻⁶ cm²/Vs or more is especially preferable.

As the substance with a high electron-transport property, for example, a metal complex having a quinoline skeleton or a benzoquinoline skeleton, such as Alq or BAlq, can be used. Alternatively, a metal complex having an oxazole-based ligand or a thiazole-based ligand, such as bis[2-(2-hydroxyphenyl)benzoxazolato]zinc (abbreviation: Zn(BOX)₂) or bis[2-(2-hydroxyphenyl)benzothiazolato]zinc (abbreviation: Zn(BTZ)₂) can be used. Alternatively, TAZ, BPhen, BCP, or the like can be used.

### <<Electron-Injection Layer 2305>

The electron-injection layer 2305 contains a substance with a high electron-injection property.

Examples of the substance with a high electron-injection property include alkali metals, alkaline earth metals, and compounds thereof, such as lithium, cesium, calcium, lithium fluoride, cesium fluoride, calcium fluoride, and lithium oxide. A rare earth metal compound such as erbium fluoride can also be used. Any of the above substances for the electron-transport layer 2304 can also be used.

### <<Charge-Generation Region>>

The charge-generation region may have either a structure in which an electron acceptor (acceptor) is added to an organic compound with a high hole-transport property or a structure in which an electron donor (donor) is added to an organic compound with a high electron-transport property. Alternatively, these structures may be stacked.

Examples of the organic compound with a high hole-transport property include the above materials that can be used for the hole-transport layer, and examples of the organic compound with a high electron-transport property include the above materials that can be used for the electron-transport layer.

As examples of the electron acceptor, 7,7,8,8-tetracyano-2,3,5,6-tetrafluoroquinodimethane (abbreviation: F4-TCNQ), chloranil, and the like can be given. In addition, transition metal oxides can be given, among which oxides of metals belonging to Groups 4 to 8 of the periodic table are preferred. Specifically, it is preferable to use vanadium oxide, niobium oxide, tantalum oxide, chromium oxide, molybdenum oxide, tungsten oxide, manganese oxide, and rhenium oxide because of their high electron accepting properties. Among these, molybdenum oxide is especially preferable because it is stable in the air, has a low hygroscopic property, and is easy to handle.

As the electron donor, it is possible to use an alkali metal, an alkaline earth metal, a rare earth metal, a metal belonging to Group 13 of the periodic table, or an oxide or a carbonate thereof. Specifically, lithium, cesium, magnesium, calcium, ytterbium, indium, lithium oxide, cesium carbonate, or the like is preferably used. Alternatively, an organic compound such as tetrathianaphthacene may be used as the electron donor.

The above-described layers included in the EL layer 2203 and the intermediate layer 2207 can be formed by any of the following methods: an evaporation method (including a vacuum evaporation method), a transfer method, a printing method, an inkjet method, a coating method, and the like.

Note that this embodiment can be combined with any of the other embodiments in this specification as appropriate.

### Embodiment 6

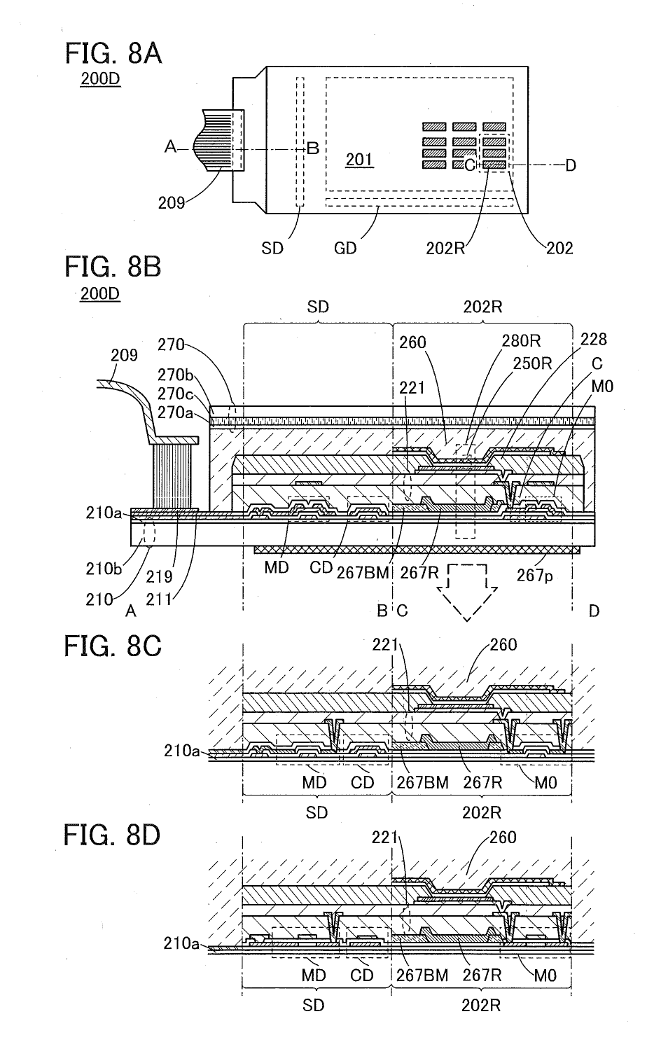

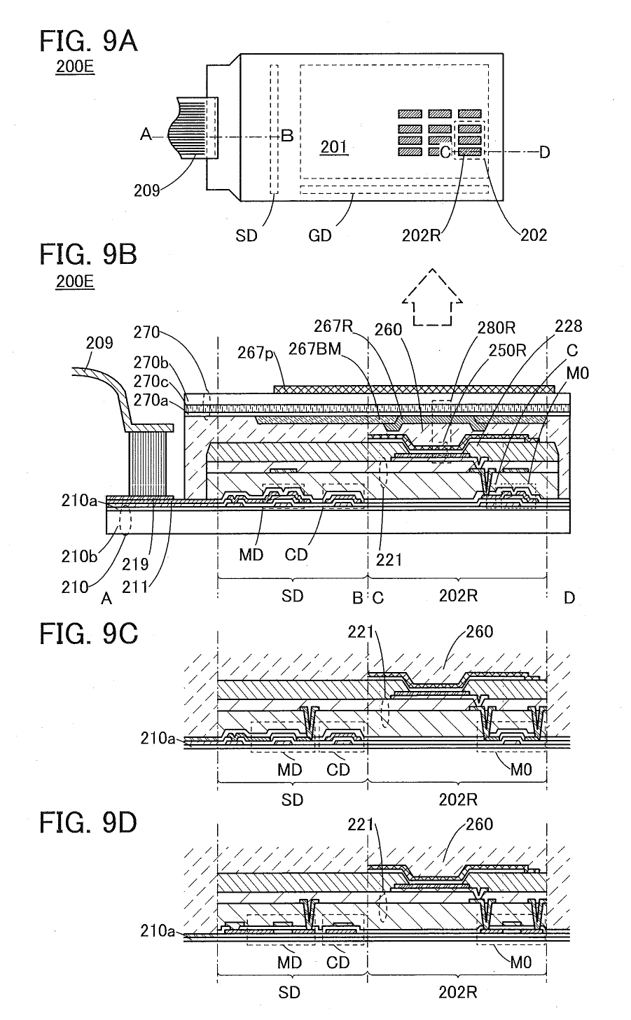

In this embodiment, a structure of a display device including a light-emitting element that can be fabricated using the film formation apparatus of one embodiment of the present invention will be described with reference to FIGS. 8A to 8D and FIGS. 9A to 9D.

FIGS. 8A to 8D illustrate structures of the display device including the light-emitting element that can be fabricated using the film formation apparatus of one embodiment of the present invention. FIG. 8A is a top view illustrating a structure of a display device 200D including the light-emitting element that can be fabricated using the film formation apparatus of one embodiment of the present invention. FIG. 8B is a cross-sectional view of the display device 200D along a section line A-B and a section line C-D in FIG. 8A.

### <<Structure Example 1 of Display Device>

The display device 200D described in this embodiment includes a base 210, a base 270 overlapping with the base 210, a bonding layer 260 between the base 210 and the base 270, a pixel 202, a driver circuit GD for supplying a control signal to the pixel 202, a driver circuit SD for supplying a display signal to the pixel 202, and a region 201 provided with the pixel 202 (see FIGS. 8A and 8B).

The base 210 includes an insulating film 210a and a base 210b.

The base 270 includes an insulating film 270a, a base 270b, and a resin layer 270c with which the insulating film 270a is attached to the base 270b.

With the bonding layer 260, the base 210 is attached to the base 270.

The pixel 202 includes a subpixel 202R and the like, and is supplied with a display signal (see FIG. 8A). Note that the pixel 202 includes the subpixel 202R for displaying red, a subpixel for displaying green, and a subpixel for displaying blue.

The subpixel 202R includes a circuit including a driving transistor M0, a capacitor C, and a display module 280R provided with a display element (see FIG. 8B).

The display module 280R includes a light-emitting element 250R and a coloring layer 267R overlapping with the light-emitting element 250R on a light-emitting side. Note that the light-emitting element 250R is one embodiment of the display element.

The light-emitting element 250R includes a lower electrode, an upper electrode, and a layer containing a light-emitting organic compound.

The circuit includes the driving transistor M0 and is provided between the base 210 and the light-emitting element 250R. The insulating film 221 is provided between the circuit and the light-emitting element 250R.

A second electrode of the driving transistor M0 is electrically connected to the lower electrode of the light-emitting element 250R through an opening provided in the insulating film 221.

A first electrode of the capacitor C is electrically connected to a gate of the driving transistor M0. A second electrode of the capacitor C is electrically connected to the second electrode of the driving transistor M0.

The driver circuit SD includes a transistor MD and a capacitor CD.

The wiring 211 is electrically connected to the terminal 219. The terminal 219 is electrically connected to a flexible printed board 209.

Note that a light-blocking layer 267BM is provided so as to surround the coloring layer 267R.

In addition, the partition wall 228 is formed so as to cover an end portion of the lower electrode of the light-emitting element 250R.

A functional film 267p may be provided in a position overlapping with the region 201 (see FIG. 8B).

Accordingly, the display device 200D can display data on the side where the base 210 is provided.

### <<Overall Structure>>

The display device 200D includes the base 210, the base 270, the bonding layer 260, the pixel 202, the driver circuit GD, the driver circuit SD, or the region 201.

### <<Base 210, Base 270>>

The base 210 includes the insulating film 210a and the base 210b.

The base 270 includes the insulating film 270a and the base 270b.

There is no particular limitation on the material for the base 210 and the base 270 as long as the bases 210 and 270 each have heat resistance high enough to withstand a manufacturing process and a thickness and a size which can be used in a manufacturing apparatus.

The same material can be used for the bases 210 and 270.

For the base 210, an organic material, an inorganic material, a composite material of an organic material and an inorganic material, or the like can be used.

For example, an inorganic material such as glass, ceramic, or metal can be used for the base 210.

Specifically, non-alkali glass, soda-lime glass, potash glass, crystal glass, or the like can be used for the base 210.

Specifically, an inorganic oxide film, an inorganic nitride film, an inorganic oxynitride film, or the like can be used for the base 210. For example, a silicon oxide film, a silicon nitride film, a silicon oxynitride film, or an alumina film can be used for the base 210.

Specifically, SUS, aluminum, or the like can be used for the base 210.

For example, an organic material such as a resin, a resin film, or plastic can be used for the base 210.

Specifically, a resin film or a resin plate of polyester, polyolefin, polyamide, polyimide, polycarbonate, an acrylic resin, or the like can be used for the base 210.

For example, a composite material such as a resin film to which a metal plate, a thin glass plate, or a film of an inorganic material is attached can be used for the base 210.

For example, a composite material formed by dispersing a fibrous or particulate metal, glass, an inorganic material, or the like into a resin film can be used for the base 210.

For example, a composite material formed by dispersing a fibrous or particulate resin, an organic material, or the like into an inorganic material can be used for the base 210.

For the base 210, a single-layer material or a stacked-layer material in which a plurality of layers are stacked can be used. For example, a stacked-layer material in which a base, an insulating film that prevents diffusion of impurities contained in the base, and the like are stacked can be used for the base 210.

Specifically, a stacked-layer material in which glass and one or a plurality of films that prevent diffusion of impurities contained in the glass and that are selected from a silicon oxide film, a silicon nitride film, a silicon oxynitride film, and the like are stacked can be used for the base 210.

Alternatively, a stacked-layer material in which a resin and a film that prevents diffusion of impurities contained in the resin, such as a silicon oxide film, a silicon nitride film, and a silicon oxynitride film are stacked can be used for the base 210.

Specifically, a stack body including the base 210b, the insulating film 210a that prevents diffusion of impurities into the light-emitting element 250R or the like, and a resin layer 210c with which the insulating film 210a is attached to the base 210b can be used.

A film capable of preventing diffusion of impurities can be used as the insulating film 210a. For example, a material that includes one or more films selected from a silicon oxide film, a silicon nitride film, a silicon oxynitride film, and the like can be used for the insulating film 210a.

### <<Bonding Layer>>

There is no particular limitation on the material for the bonding layer 260 as long as the bonding layer 260 attaches the base 210 and the base 270 to each other.

An inorganic material, an organic material, a composite material of an inorganic material and an organic material, or the like can be used for the bonding layer 260.

For example, a glass layer with a melting point of 400° C. or lower, preferably 300° C. or lower, or an adhesive can be used as the bonding layer 260.

For example, an organic material such as a light curable adhesive, a reactive curable adhesive, a thermosetting adhesive, and/or an anaerobic adhesive can be used for the bonding layer 260.

Specifically, an adhesive containing an epoxy resin, an acrylic resin, a silicone resin, a phenol resin, a polyimide resin, an imide resin, a polyvinyl chloride (PVC) resin, a polyvinyl butyral (PVB) resin, and an ethylene vinyl acetate (EVA) resin, or the like can be used.

### <<Pixel>>

A variety of transistors can be used as the driving transistor M0.

For example, a transistor in which a Group 14 element, a compound semiconductor, an oxide semiconductor, or the like is used for the semiconductor layer can be used. Specifically, a semiconductor containing silicon, a semiconductor containing gallium arsenide, an oxide semiconductor containing indium, or the like can be used for the semiconductor layer of the driving transistor M0.

For example, single crystal silicon, polysilicon, or amorphous silicon can be used for the semiconductor layer of the driving transistor M0.

For example, a bottom-gate transistor or a top-gate transistor can be used.

A variety of display elements can be used in the display module 280R. For example, an organic EL element which includes a lower electrode, an upper electrode, and a layer containing a light-emitting organic compound between the lower electrode and the upper electrode can be used as the display element.

Note that in the case where a light-emitting element is used as the display element, a light-emitting element combined with a microcavity structure can be used. For example, the microcavity structure may be formed using the lower electrode and the upper electrode of the light-emitting element so that light with a specific wavelength can be extracted from the light-emitting element efficiently.

Specifically, a reflective film which reflects visible light is used as one of the upper and lower electrodes, and a semi-transmissive and semi-reflective film which transmits part of visible light and reflects part of visible light is used as the other. The upper electrode is located with respect to the lower electrode so that light with a specific wavelength can be extracted efficiently.

For example, a layer which emits light including red, green, and blue light can be used as the layer containing a light-emitting organic compound. In addition, a layer which emits light including yellow light can also be used as the layer containing a light-emitting organic compound.

As the coloring layer 267R, a layer containing a material such as a pigment or a dye can be used. Accordingly, the display module 280R can emit light of a particular color.

For example, a microcavity for extracting red light efficiently and a coloring layer which transmits red light may be used in the display module 280R for displaying red, a microcavity for extracting green light efficiently and a coloring layer which transmits green light may be used in a display module for displaying green, or a microcavity for extracting blue light efficiently and a coloring layer which transmits blue light may be used in a display module for displaying blue light.

Furthermore, a microcavity for extracting yellow light efficiently and a coloring layer which transmits yellow light may be used in a display module.

### <<Driver Circuit>>

A variety of transistors can be used as the transistor MD of the driver circuit SD. For example, the transistor MD can have the same structure as the driving transistor M0.

In the case where the capacitor C is used, the capacitor CD can have the same structure as the capacitor C.

### <<Region>>

The region 201 includes a plurality of pixels 202 arranged in a matrix. The region 201 can display the display data and can supply the sensing data associated with coordinates data of the pixels provided in the region 201. For example, the region 201 can sense the presence or absence of an object located close to the region 201 and can supply the result together with coordinates data.

### <<Others>>

A conductive material can be used for the wiring 211 or the terminal 219.

For example, an inorganic conductive material, an organic conductive material, metal, or conductive ceramic can be used for the wiring.

Specifically, a metal element selected from aluminum, gold, platinum, silver, chromium, tantalum, titanium, molybdenum, tungsten, nickel, iron, cobalt, palladium, and manganese; an alloy including any of the above-described metal elements; an alloy including any of the above-described metal elements in combination; or the like can be used for the wiring or the like.

Alternatively, a conductive oxide such as indium oxide, indium tin oxide, indium zinc oxide, zinc oxide, or zinc oxide to which gallium is added can be used.

Alternatively, graphene or graphite can be used. A film containing graphene can be formed, for example, by reducing a film containing graphene oxide. Examples of a reducing method include a method with application of heat and a method using a reducing agent.

Alternatively, a conductive high molecule can be used.

For the light-blocking layer 267BM, a light-blocking material can be used. For example, a resin in which a pigment is dispersed, a resin containing a dye, or an inorganic film such as a black chromium film can be used for the light-blocking layer 267BM. For the light-blocking layer 267BM, carbon black, an inorganic oxide, a composite oxide containing a solid solution of a plurality of inorganic oxides, or the like can be used.

An insulating material can be used for the partition wall 228. For example, an inorganic material, an organic material, or a stacked-layer material of an inorganic material and an organic material can be used. Specifically, a film containing silicon oxide, silicon nitride, or the like, acrylic, polyimide, a photosensitive resin, or the like can be used.

The functional film 267p can be provided on the display surface side of the display device. For example, an inorganic material, an organic material, or a composite material of an inorganic material and an organic material can be used for the functional film 267p. Specifically, a ceramic coat layer containing alumina, silicon oxide, or the like, a hard coat layer containing a UV curable resin or the like, an anti-reflection film, a circularly polarizing plate, or the like can be used.

For example, in this specification and the like, a display element, a display device which is a device including a display element, a light-emitting element, and a light-emitting device which is a device including a light-emitting element can employ a variety of modes or can include a variety of elements. The display element, the display device, the light-emitting element, or the light-emitting device includes at least one of an electroluminescent (EL) element (e.g., an EL element including organic and inorganic materials, an organic EL element, or an inorganic EL element), an LED (e.g., a white LED, a red LED, a green LED, or a blue LED), a transistor (a transistor that emits light depending on current), an electron emitter, a liquid crystal element, electronic ink, an electrophoretic element, a grating light valve (GLV), a plasma display panel (PDP), a display element using micro electro mechanical systems (MEMS), a digital micromirror device (DMD), a digital micro shutter (DMS), MIRASOL (registered trademark), an interferometric modulator display (IMOD) element, a MEMS shutter display element, an optical-interference-type MEMS display element, an electrowetting element, a piezoelectric ceramic display, a display element including a carbon nanotube, and the like. Other than the above, a display medium whose contrast, luminance, reflectance, transmittance, or the like is changed by an electric or magnetic effect may be included. Examples of a display device having an EL element include an EL display. Display devices having electron emitters include a field emission display (FED), an SED-type flat panel display (SED: surface-conduction electron-emitter display), and the like. Examples of display devices including liquid crystal elements include a liquid crystal display (e.g., a transmissive liquid crystal display, a transflective liquid crystal display, a reflective liquid crystal display, a direct-view liquid crystal display, or a projection liquid crystal display). Examples further include a display device including electronic ink, Electronic Liquid Powder (registered trademark), or an electrophoretic element, such as electronic paper. In the case of a transflective liquid crystal display or a reflective liquid crystal display, some or all of pixel electrodes function as reflective electrodes. For example, some or all of pixel electrodes are formed to contain aluminum, silver, or the like. In such a case, a memory circuit such as an SRAM can be provided under the reflective electrodes, leading to lower power consumption. Note that in the case of using an LED, graphene or graphite may be provided under an electrode. Graphene or graphite may be a multilayer film in which a plurality of layers are stacked. Such provision of graphene or graphite enables an n-type GaN semiconductor layer including crystals to be easily formed thereover. Note that an AlN layer may be provided between the n-type GaN semiconductor layer including crystals and graphene or graphite. The GaN semiconductor layer may be formed by MOCVD. Note that when the graphene is provided, the GaN semiconductor layer can also be formed by a sputtering method.

For example, in this specification and the like, an active matrix method in which an active element is included in a pixel or a passive matrix method in which an active element is not included in a pixel can be used.

In an active matrix method, as an active element (a non-linear element), not only a transistor but also various active elements (non-linear elements) can be used. For example, an MIM (metal insulator metal) or a TFD (thin film diode) can also be used. Since such an element has few numbers of manufacturing steps, manufacturing cost can be reduced or yield can be improved. Alternatively, since the size of the element is small, the aperture ratio can be improved, so that power consumption can be reduced or higher luminance can be achieved.

As a method other than the active matrix method, the passive matrix method in which an active element (a non-linear element) is not used can also be used. Since an active element (a non-linear element) is not used, the number of manufacturing steps is small, so that manufacturing cost can be reduced or yield can be improved. Alternatively, since an active element (a non-linear element) is not used, the aperture ratio can be improved, so that power consumption can be reduced or higher luminance can be achieved, for example.

Note that an example of the display device is shown here; however, one embodiment of the present invention is not limited thereto. For example, data is not necessarily displayed. As an example, the display device may be used as a lighting device. By using the device as a lighting device, it can be used as interior lighting having an attractive design. Alternatively, it can be used as lighting from which light radiates in various directions. Further alternatively, it may be used as a light source, for example, a backlight or a front light. In other words, it may be used as a lighting device for the display panel.

### <Modification Example 1 of Display Portion>

A variety of transistors can be used in the display device 200D.

Structures in which bottom-gate transistors are used in the region 201 are illustrated in FIGS. 8B and 8C.

For example, a semiconductor layer containing an oxide semiconductor, amorphous silicon, or the like can be used in the driving transistor M0 and the transistor MD shown in FIG. 8B.

For example, a film represented by an In-M-Zn oxide that contains at least indium (In), zinc (Zn), and M (a metal such as Al, Ga, Ge, Y, Zr, Sn, La, Ce, or Hf) is preferably included. Alternatively, both In and Zn are preferably contained.

As a stabilizer, gallium (Ga), tin (Sn), hafnium (Hf), aluminum (Al), zirconium (Zr), or the like can be given. As another stabilizer, lanthanoid such as lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tin), ytterbium (Yb), or lutetium (Lu) can be given.

As an oxide semiconductor included in an oxide semiconductor film, any of the following can be used, for example: an In—Ga—Zn-based oxide, an In—Al—Zn-based oxide, an In—Sn—Zn-based oxide, an In—Hf—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, an In—Lu—Zn-based oxide, an In—Sn—Ga—Zn-based oxide, an In—Hf—Ga—Zn-based oxide, an In—Al—Ga—Zn-based oxide, an In—Sn—Al—Zn-based oxide, an In—Sn—Hf—Zn-based oxide, an In—Hf—Al—Zn-based oxide, and an In—Ga-based oxide.

Note that here, an “In—Ga—Zn-based oxide” means an oxide containing In, Ga, and Zn as its main components and there is no limitation on the ratio of In:Ga:Zn. The In—Ga—Zn-based oxide may contain another metal element in addition to In, Ga, and Zn.

For example, a semiconductor layer containing polycrystalline silicon that is obtained by crystallization process such as laser annealing can be used in the driving transistor M0 and the transistor MD shown in FIG. 8C.

A structure in which top-gate transistors are used in the display device 200D is shown in FIG. 8D.

For example, a semiconductor layer containing polycrystalline silicon, a single crystal silicon film that is transferred from a single crystal silicon substrate, or the like can be used in the driving transistor M0 and the transistor MD shown in FIG. 8D.

### <Structure Example 2 of Display Device>

FIGS. 9A to 9D illustrate a structure of a display device of one embodiment of the present invention. FIG. 9A is a top view of a display device 200E in one embodiment of the present invention, and FIG. 9B is a cross-sectional view including cross sections taken along lines A-B and C-D in FIG. 9A.

The display device 200E described in this embodiment is different from the display device 200D described with reference to FIGS. 8A to 8D in that the coloring layer 267R and the light-blocking layer 267BM surrounding the coloring layer 267R are provided between the base 270 and the light-emitting element 2508, that the functional film 26′7p is provided on the base 270 side, and that the display module 280R emits light to the side where the base 270 is provided. As the other components, similar components can be used.

Accordingly, the display device 200E can display data on the side where the base 270 is provided. In addition, the display device 200E can supply sensing data by sensing an object that is located close to or in contact with the side where the base 270 is provided.

Note that this embodiment can be combined with any of the other embodiments in this specification as appropriate.

### Embodiment 7

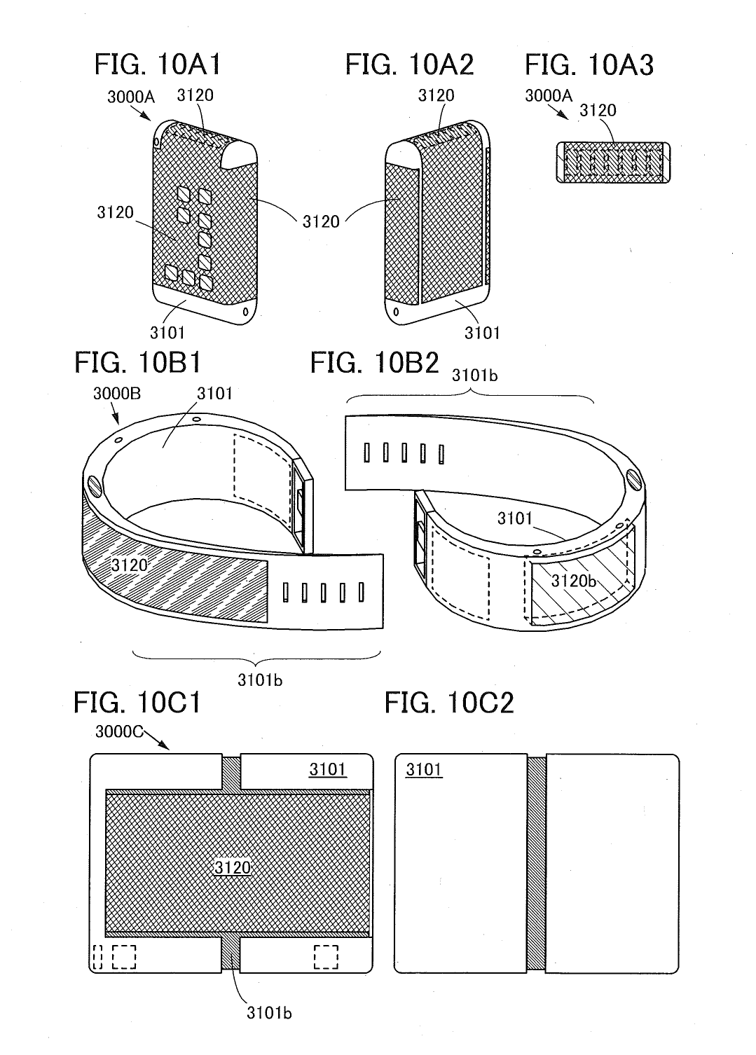

In this embodiment, a structure of a data processing device in which a light-emitting element that can be manufactured using the film formation apparatus of one embodiment of the present invention is provided in an input/output portion will be described with reference to FIGS. 10A1, 10A2, 10A3, 10B1, 10B2, 10C1, and 10C2. Note that the data processing device in which a light-emitting element is provided in an input/output portion can also be used for a lighting device.

FIGS. 10A1, 10A2, 10A3, 10B1, 10B2, 10C1, and 10C2 illustrate the data processing devices of one embodiment of the present invention.

FIGS. 10A1 to 10A3 are projection views illustrating a data processing device of one embodiment of the present invention.

FIGS. 10B 1 and 10B2 are projection views illustrating a data processing device of one embodiment of the present invention.

FIGS. 10C1 and 10C2 are a top view and a bottom view illustrating a data processing device of one embodiment of the present invention.

### <<Data Processing Device A>>

A data processing device 3000A includes an input/output portion 3120 and a housing 3101 supporting the input/output portion 3120 (see FIGS. 10A1 to 10A3).

The data processing device 3000A further includes an arithmetic portion, a memory portion storing a program that is executed by the arithmetic portion, and a power source such as a battery supplying power for driving the arithmetic portion.

Note that the housing 3101 stores the arithmetic portion, the memory portion, the battery, and the like.

The data processing device 3000A can display data on its side surface and/or top surface.

A user of the data processing device 3000A can supply operation instructions by using a finger in contact with the side surface and/or the top surface.

### <<Data Processing Device B>>

A data processing device 3000B includes the input/output portion 3120 and an input/output portion 3120b (see FIGS. 10B1 and 10B2).

The data processing device 3000B further includes the housing 3101 and a belt-shaped flexible housing 3101b that support the input/output portion 3120.

The data processing device 3000B further includes the housing 3101 supporting the input/output portion 3120b.

The data processing device 3000B further includes an arithmetic portion, a memory portion storing a program that is executed by the arithmetic portion, and a power source such as a battery supplying power for driving the arithmetic portion

Note that the housing 3101 stores the arithmetic portion, the memory portion, the battery, and the like.

The data processing device 3000B can display data on the input/output portion 3120 supported by the belt-shaped flexible housing 3101b.

A user of the data processing device 3000B can supply operation instructions by using a finger in contact with the input/output portion 3120.

### <<Data Processing Device C>>

A data processing device 3000C includes the input/output portion 3120 and the housings 3101 and 3101b supporting the input/output portion 3120 (see FIGS. 10C1 and 10C2).

The input/output portion 3120 and the housing 3101b have flexibility.

The data processing device 3000C further includes an arithmetic portion, a memory portion storing a program that is executed by the arithmetic portion, and a power source such as a battery supplying power for driving the arithmetic portion.

Note that the housing 3101 stores the arithmetic portion, the memory portion, the battery, and the like.

The data processing device 3000C can be folded in two at the housing 3101b.

Note that this embodiment can be combined with any of the other embodiments in this specification as appropriate.

Note that in this specification and the like, part of a diagram or text described in one embodiment can be taken out to constitute one embodiment of the invention. Thus, in the case where a diagram or text related to a certain portion is described, the contents taken out from part of the diagram or the text are also disclosed as one embodiment of the invention, and one embodiment of the invention can be constituted. The embodiment of the present invention is clear. Therefore, for example, in a diagram or text in which one or more active elements (e.g., transistors or diodes), wirings, passive elements (e.g., capacitors or resistors), conductive layers, insulating layers, semiconductor layers, organic materials, inorganic materials, components, devices, operating methods, manufacturing methods, or the like are described, part of the diagram or the text is taken out, and one embodiment of the invention can be constituted. For example, from a circuit diagram in which N circuit elements (e.g., transistors or capacitors; N is an integer) are provided, it is possible to take out M circuit elements (e.g., transistors or capacitors; M is an integer, where M<N) and constitute one embodiment of the invention. For another example, it is possible to take out M layers (M is an integer, where M<N) from a cross-sectional view in which N layers (N is an integer) are provided and constitute one embodiment of the invention. For another example, it is possible to take out M elements (M is an integer, where M<N) from a flowchart in which N elements (N is an integer) are provided and constitute one embodiment of the invention. For another example, it is possible to take out some given elements from a sentence “A includes B, C, D, E, or F” and constitute one embodiment of the invention, for example, “A includes B and E”, “A includes E and F”, “A includes C, E, and F”, or “A includes B, C, D, and E”.

Note that in the case where at least one specific example is described in a diagram or text described in one embodiment in this specification and the like, it will be readily appreciated by those skilled in the art that a broader concept of the specific example can be derived. Therefore, in the diagram or the text described in one embodiment, in the case where at least one specific example is described, a broader concept of the specific example is disclosed as one embodiment of the invention, and one embodiment of the invention can be constituted. The embodiment of the present invention is clear.

Note that in this specification and the like, what is illustrated in at least a diagram (which may be part of the diagram) is disclosed as one embodiment of the invention, and one embodiment of the invention can be constituted. Therefore, when certain contents are described in a diagram, the contents are disclosed as one embodiment of the invention even when the contents are not described with text, and one embodiment of the invention can be constituted. In a similar manner, part of a diagram, which is taken out from the diagram, is disclosed as one embodiment of the invention, and one embodiment of the invention can be constituted. The embodiment of the present invention is clear.

This application is based on Japanese Patent Application serial No. 2014-191234 filed with Japan Patent Office on Sep. 19, 2014, the entire contents of which are hereby incorporated by reference.

What is claimed is:

1. A film formation apparatus comprising:
a film formation chamber comprising:
a processed member support, an evaporation source, and an adhesive layer,
wherein the processed member support is configured to support a processed member,
wherein the evaporation source is configured to eject a film formation material that is to be attached to the processed member,
wherein the film formation material is to be attached to the adhesive layer, and
wherein the adhesive layer includes a region facing the evaporation source.

2. The film formation apparatus according to claim 1, further comprising a shadow mask support in the film formation chamber,
wherein the shadow mask support is configured to support a shadow mask between the processed member and the evaporation source, and
wherein the adhesive layer is on the shadow mask so as to have a region facing the evaporation source.

3. The film formation apparatus according to claim 1, wherein the adhesive layer with a width of 25 mm has an adhesion strength of 1 N to 20 N.

4. The film formation apparatus according to claim 1, further comprising:
a plasma source from which plasma is delivered to the adhesive layer; and
a plasma source support which supports the plasma source and moves relatively to the adhesive layer.

5. The film formation apparatus according to claim 1,
wherein the evaporation source is an first evaporation source,
wherein the film formation chamber comprises a second evaporation source different from the first evaporation source.

6. The film formation apparatus according to claim 1,
wherein the adhesive layer is on an inner wall of the film formation chamber.

7. The film formation apparatus according to claim 1,
wherein the adhesive layer is on an attachment protection plate.

8. A film formation method, comprising:
evacuating a film formation chamber;
ejecting a film formation material so that the film formation material is deposited on a surface of a processed member while part of the film formation material is attached to an adhesive layer; and
delivering plasma from a plasma source to the adhesive layer to remove the film formation material.

9. A film formation method according to claim 8,
wherein the film formation material is a first film formation material, and
wherein a film formation material is ejected from a second evaporation source different from a first evaporation source of the first film formation material.

10. A shadow mask comprising a shielding region and an opening region,
wherein the shielding region includes a base and a resin layer, and
wherein the resin layer is configured to be separated from the base.

11. The shadow mask according to claim 10,
wherein the resin layer includes a protruding part,
wherein the protruding part is adjacent to the opening region, and
wherein the protruding part is narrower than the shielding region.

12. The shadow mask according to claim 10, further comprising an adhesive layer,
wherein the shielding region is configured to shield a film formation material,
wherein the opening region is surrounded by the shielding region, and
wherein the adhesive layer is on a surface of the shielding region.
